(19) United States
(12) Patent Application Publication
(10) Pub. No.: US 2026/0003010 A1
(43) Pub. Date: Jan. 1, 2026

(54) PREDICTIVE BATTERY ANALYSIS

(71) Applicant: Studsvik Inc., Wilmington, NC (US)

(72) Inventors: Benjamin P. Youman, Davis Junction, IL (US); Justin Robert Smith, Bettendorf, IA (US); Mason Edwards Krei, Idaho City, ID (US)

(21) Appl. No.: 19/256,005

(22) Filed: Jun. 30, 2025

Related U.S. Application Data
(60) Provisional application No. 63/666,360, filed on Jul. 1, 2024.

(51) Int. Cl. G01R 31/396; G01R 31/392; H01M 10/42; H02J 7/00; H02J 9/06

(52) U.S. Cl. CPC G01R 31/396; G01R 31/392; H01M 10/4285; H02J 7/0013; H02J 7/005; H02J 9/06

(57) ABSTRACT

A system includes a battery assembly, a control board, a first load control board, and a second load control board. The control board may be configured to implement a diagnostic load test of the battery assembly by controlling the first load control board and the second load control board to discharge the battery assembly. The first load control board may discharge the battery assembly according to a first current for a first duration and the second load control board may discharge the battery assembly according to a second current for a second duration. The control board may collect battery data to determine a state of health of the battery assembly.

### RELATED APPLICATIONS

This application claims priority to U.S. Provisional Application No. 63/666,360, filed Jul. 1, 2024, titled “Predictive Battery Analysis,” which is incorporated by reference herein in its entirety.

### BACKGROUND

Backup power systems are critical components of the resilience industry as they enable organizations to recover from disruptions such as natural disasters and infrastructure failures. Backup power systems, such as uninterruptible power supply (UPS) systems and battery energy storage systems (BESS), can use rechargeable batteries that are designed to provide backup power during electrical outages.

### SUMMARY

Backup power systems can be used as emergency sources of power when the electricity goes out, by ensuring that electricity continues to be provided to connected devices and systems during a power outage or voltage fluctuation. They are crucial for maintaining the operation of critical systems such as nuclear facilities, healthcare facilities, and data centers when power is abruptly cut off. By continuing to provide power during power outages or voltage fluctuations, backup power systems can also prevent data loss and equipment damage.

Backup power systems can include battery backup power systems such as UPS systems and BESS. Some of these battery backup power systems use rechargeable batteries. Consequently, battery health is crucial to ensure the reliability and longevity of battery backup power systems. A battery's health can degrade due to use, environment, abuse, and many other known and unknown factors. This makes the decline in battery performance expected, but also variable and difficult to predict, with a battery's calendar age a less reliable method to determine performance. Additionally, because site loads and environmental factors play a role, every installation is unique and can cause batteries to age at a different rate. Being able to immediately and accurately predict the battery state-of-health, such as how long a battery can provide power and its service life, is an essential operational, planning, and maintenance tool.

To ensure that a battery backup power system is ready to provide electrical power during an outage, its batteries must be routinely tested, Current battery test methods can include physical inspection, electrochemical testing, impedance testing, or load bank testing via external loads, to assess the capacity, internal resistance, and/or state of health of a respective battery. However, these methods tend to be time-consuming. For example, a battery test can take hours or days to complete, depending on the capacity of the battery backup power system and the amount of load applied during the test. Performing battery tests can be costly due to the need to use expensive load banks and other monitoring equipment. They may also require removal of the batteries from the system to test. In some instances, performing a battery test can cause the backup batteries to be significantly discharged, leading to additional time to charge the batteries to full capacity. In some circumstances, an organization may need to rent or procure a spare battery backup power system while its primary battery backup system undergoes these tests. Furthermore, depending on which tests are implemented, they may not give a comprehensive picture of the health of the battery.

Accordingly, there is a need for improved systems, devices, and methods that can provide a comprehensive diagnosis of the health of batteries in battery backup power systems at lower cost, shorter times, and without significantly discharging the batteries during these tests.

Some embodiments of the present disclose provide a technical solution to the aforementioned technical problems, by integrating and automating battery diagnostics and predictive capabilities within a battery power system. In accordance with some embodiments, a battery power system (e.g., battery operated power system or battery backup power system) can include a load control board (e.g., a circuit board) with one or more independent circuits. Each of the circuits is specifically designed to implement a diagnostic test on a respective battery, or on a respective subset of batteries, of the power battery system. In some embodiments, the one or more circuits include a first circuit that is configured to implement a constant current test. In some embodiments, the one or more circuits include a second circuit that is configured to implement a “high” current test (e.g., higher current compared to constant current). As used herein, the constant current test is also known as a voltage over time test or a “V/T test”. The high current test is also known as an impulse discharge test or a “Vdiff test”.

As disclosed, in some embodiments, the V/T tests and Vdiff tests are performed by selecting voltage values of the batteries that lie within an exponential region of the discharge curve of the battery. The exponential region of a battery discharge curve refers to the initial part of the discharge where the voltage drops rapidly. In accordance with some embodiments, performing the battery tests by according to voltage values that lie within the exponential region of the discharge curve of the battery can help predict battery life and battery health because the battery characteristics in this region can be correlated to battery health (e.g., are trendable). In some embodiments, the V/T and Vdiff tests are executed sequentially (e.g., one or more V/T tests followed by one or more Vdiff tests, or vice versa, or in any sequence). In some embodiments, the V/T and Vdiff tests are executed sequentially at predefined time intervals (e.g., once every month, or once every three months).

As disclosed, in some embodiments, a respective V/T test takes about 3-10 minutes to complete, and involves measuring voltage decay of a respective battery (or a subset of batteries) by applying a fixed load to the respective battery (or the subset), such that the respective battery (or the subset) decays from a first predefined voltage value to a second predefined voltage value. As used herein, the load to the battery is applied by specifying (e.g., adjusting or programming) a resistance value on one or more load resistors (or power resistors) on load control boards so that it results in a current drain (e.g., in amperes) of a certain percentage of the battery capacity (e.g., in ampere-hours). The time taken for the voltage to decrease from the first voltage value to the second voltage value is recorded and is indicative of battery health. In accordance with some embodiments, the first and second voltage values are selected to be within the exponential region of the battery discharge curve, because the battery characteristics in this region are trendable. The time taken for the battery voltage drops from the first voltage value to the second voltage value can be repeatable and trendable, and can provide an indication of battery health. For example, a healthier battery takes a longer time to discharge from the first voltage value to the second voltage value compared to a less healthy battery. In some embodiments, the V/T test is performed by selecting (e.g., by the system) a resistor value in the first circuit such that it provides a constant load (e.g., current) that is around 1-3% of the load battery current capability (e.g., expressed in ampere-hours).

As disclosed, a respective Vdiff test takes about a few seconds up to under 5 minutes to complete. The Vdiff test involves applying a larger fixed load (e.g., around 8-12% of the load battery capacity) to a battery. Suppose the battery (or string of batteries) is at a third voltage value when the Vdiff test commences. When the load is applied, the voltage value of the battery (or battery string) decreases to a fourth voltage value. When the load is removed, the voltage will “spring back” (i.e., increase) from the fourth voltage value to a fifth voltage value that is higher than the fourth voltage value. The difference between the third voltage value and the fifth voltage value is indicative of battery health. For example, a smaller difference (i.e., a larger “spring back” value) is indicative of a healthier battery whereas a bigger difference (i.e., less spring back) is indicative of a less healthy battery.

In some embodiments, the Vdiff test is performed by selecting the third voltage value, the discharge time, and/or the fourth voltage value such that the third voltage value, the fourth voltage value, and the fifth voltage value are within an exponentially decaying region of the battery discharge curve. This ensures that the difference in voltage (e.g., difference between third and fifth voltage values, or difference between fifth and fourth voltage values) is repeatable and trendable. In some embodiments, the Vdiff test is performed by selecting (e.g., by the system) a resistor value in the second circuit such that it provides a load (e.g., current) that is around 8-12% of the load battery current capability (e.g., expressed in ampere-hours).

In accordance with some embodiments, the advantages of the disclosed implementations include: (i) reduced time to perform the disclosed tests compared to existing battery test methods, because the Vdiff and V/T tests take minutes to complete, instead of hours or days with current testing methods; (ii) reduced cost by eliminating labor and external equipment resources required to check functionality/capability of battery by integrating and automating battery diagnostics and predictive capabilities within a battery power system; (iii) the tests do not significantly discharge the batteries, thereby eliminating the need for another battery power backup system while the tests are performed; and (iv) ability to diagnose and predict battery health in battery systems of different capacities (e.g., 100 Ah to 1000 Ah, to over 1000 Ah), through the implementation of a load control board that has high current-carrying capacity as well as being the capability to apply appropriate resistance values for the Vdiff and V/T tests.

In accordance with some embodiments, methods, apparatuses, and systems for predictive battery analysis are described. A system may include a battery assembly, a control board, a first load control board, and a second load control board. The control board may be configured to implement a diagnostic load test of the battery assembly by controlling the first load control board and the second load control board to discharge the battery assembly. The first load control board may be configured to discharge the battery assembly according to a first current for a first duration and the second load control board may be configured to discharge the battery assembly according to a second current for a second duration. The control board may collect battery data to determine a state of health of the battery assembly.

In accordance with some embodiments an apparatus comprises a battery assembly connected to a power system. The apparatus comprises a first load control board configured to draw a first current from the battery assembly. The apparatus comprises a second load control board configured to draw a second current from the battery assembly. The apparatus comprises a control board configured to (i) cause a first disconnection of the battery assembly from the power system; (ii) cause, based on sending a first command to the first load control board, the first load control board to discharge the battery assembly at a first time point based on drawing the first current from the battery assembly; (iii) cause a first reconnection of the battery assembly to the power system to recharge the battery assembly; (iv) cause, based on the recharge of the battery assembly, a second disconnection of the battery assembly from the power system; (v) cause, based on sending a second command to the second load control board, the second load control board to discharge the battery assembly at a second time point based on drawing the second current from the battery assembly; and (vi) cause a second reconnection of the battery assembly to the power system.

In accordance with some embodiments an apparatus comprises a battery assembly connected to a power system. The apparatus comprises a first load control board configured to draw a first current from the battery assembly. The apparatus comprises a second load control board configured to draw a second current from the battery assembly. The apparatus comprises a control board configured to (i) cause, based on sending a first command to the first load control board, the first load control board to discharge the battery assembly at a first time point for a first duration based on drawing the first current from the battery assembly; (ii) cause, based on sending a second command to the second load control board, the second load control board to discharge the battery assembly at a second time point for a second duration based on drawing the second current from the battery assembly; and (iii) cause a reconnection of the battery assembly to the power system.

In accordance with some embodiments a method is performed by a computing device that includes one or more processors and memory. The method comprises determining, by the computing device, one or more first values associated with one or more parameters of a battery assembly. The method comprises determining, based on a first discharge of the battery assembly according to a first current, one or more second values associated with the one or more parameters of the battery assembly. The method comprises determining, based on a first recharge of the battery assembly, one or more third values associated with the one or more parameters of the battery assembly. The method comprises determining, based on the one or more first values, the one or more second values, and the one or more third values, first state of health information associated with the battery assembly. The method comprises determining, based on a second discharge of the battery assembly according to a second current, one or more fourth values associated with the one or more parameters of the battery assembly. The method comprises determining, based on a second recharge of the battery assembly, one or more fifth values associated with the one or more parameters of the battery assembly. The method comprises determining, based on the one or more third values, the one or more fourth values, and the one or more fifth values, second state of health information associated with the battery assembly. The method comprises determining, based on the first state of health information and the second state of health information, a state of health of one or more cells of the battery assembly.

In accordance with some embodiments, a method comprises causing, by a computing device, a battery assembly to disconnect from a power system to perform one or more diagnostic load tests of the battery assembly. The method comprises determining, at one or more time points, based on the one or more diagnostic load tests of the battery assembly, one or more values associated with one or more parameters of the battery assembly. The method comprises determining, based on the one or more values, a state of health of the battery assembly.

Thus, systems, methods and apparatuses for integrated battery diagnostics are disclosed.

Note that the various embodiments described above can be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes and may not have been selected to delineate or circumscribe the inventive subject matter. Other details and features will be described in the sections that follow.

### BRIEF DESCRIPTION OF THE DRAWINGS

In order to provide understanding techniques described, the figures provide non-limiting examples in accordance with one or more implementations of the present disclosure, in which:

FIG. 1 shows an example battery analysis system, in accordance with some embodiments.

FIG. 2 shows example control board components, in accordance with some embodiments.

FIG. 3 shows an example circuitry in accordance with some embodiments.

FIGS. 4A and 4B show an example circuitry in accordance with some embodiments.

FIG. 5 shows an example battery management system in accordance with some embodiments.

FIG. 6A illustrates an example battery discharge curve, in accordance with some embodiments.

FIG. 6B shows an example battery response curve in response to a discharge impulse applied to the battery, in accordance with some embodiments.

FIGS. 7A and 7B are example test curves utilized for predictive analysis in accordance with some embodiments.

FIG. 7C illustrates an example test curve, in accordance with some embodiments.

FIG. 7D illustrates an example test curve, in accordance with some embodiments.

FIG. 8 shows a flowchart of an example method for battery predictive analysis, in accordance with some embodiments.

FIG. 9 shows a flowchart of an example method for battery predictive analysis, in accordance with some embodiments.

### DETAILED DESCRIPTION

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another configuration includes from the one particular value and/or to the other particular value. When values are expressed as approximations, by use of the antecedent “about,” it will be understood that the particular value forms another configuration. It will be further understood that the endpoints of each of the ranges are significant both in relation to the other endpoint, and independently of the other endpoint.

It is understood that when combinations, subsets, interactions, groups, etc. of components are described that, while specific reference of each various individual and collective combinations and permutations of these may not be explicitly described, each is specifically contemplated and described herein. This applies to all parts of this application including, but not limited to, steps in described methods. Thus, if there are a variety of additional steps that may be performed it is understood that each of these additional steps may be performed with any specific configuration or combination of configurations of the described methods.

As will be appreciated by one skilled in the art, hardware, software, or a combination of software and hardware may be implemented. Furthermore, the methods and systems may take the form of a computer program product on a computer-readable storage medium (non-transitory) having processor-executable instructions (e.g., computer software) embodied in the storage medium. Any suitable computer-readable storage medium may be utilized including hard disks, CD-ROMs, optical storage devices, magnetic storage devices, memresistors, Non-Volatile Random Access Memory (NVRAM), flash memory, or a combination thereof.

Throughout this application, reference is made to block diagrams and flowcharts. It will be understood that each block of the block diagrams and flowcharts, and combinations of blocks in the block diagrams and flowcharts, respectively, may be implemented by processor-executable instructions. These processor-executable instructions may be loaded onto a computer (e.g., a special purpose computer), or other programmable data processing apparatus to produce a machine, such that the processor-executable instructions which execute on the computer or other programmable data processing apparatus create a device for implementing the functions specified in the flowchart block or blocks.

This detailed description may refer to a given entity performing some action. It should be understood that this language may in some cases mean that a system (e.g., a computer) owned and/or controlled by the given entity is actually performing the action.

Blocks of the block diagrams and flowcharts support combinations of devices for performing the specified functions, combinations of steps for performing the specified functions and program instruction means for performing the specified functions. It will also be understood that each block of the block diagrams and flowcharts, and combinations of blocks in the block diagrams and flowcharts, may be implemented by special purpose hardware-based computer systems that perform the specified functions or steps, or combinations of special purpose hardware and computer instructions.

The method steps recited throughout this disclosure may be combined, omitted, rearranged, or otherwise reorganized with any of the figures presented herein and are not intended to be limited to the four corners of each sheet presented.

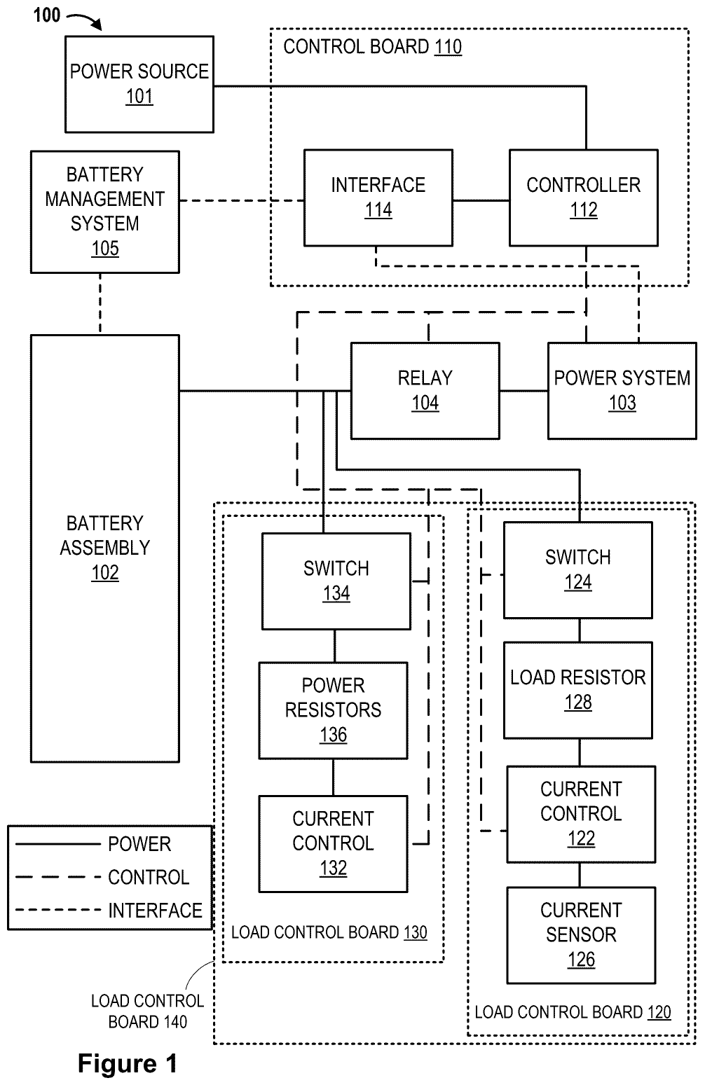

FIG. 1 shows an example battery analysis system 100, in accordance with some embodiments. In some embodiments, the battery analysis system 100 is a battery backup power system, such as a UPS system or a BESS, for industrial applications. In some embodiments, the battery analysis system 100 is a UPS system or a BESS that is configured to be used for applications requiring near-instantaneous protection from input power interruptions.

In accordance with some embodiments, the battery analysis system 100 is configured with self-diagnostic technology to monitor and predict the battery health of batteries and/or battery strings of the battery assembly 102. In some embodiments, the self-diagnostic technology comprises integrated test circuitry (e.g., implemented via control board 110, load control board 120, load control board 130, and/or load control board 140) that is integrated as part of the battery assembly 102. Specifically, in some embodiments, the battery analysis system 100 is configured to perform one or more diagnostic tests, such as one or more Vdiff tests and/or one or more V/T tests, by applying relatively small loads (e.g., around 8-12% of the battery capacity for a Vdiff test, and around 1-3% of the battery capacity for a V/T test) and over a short time duration (e.g., a few seconds or no more than 3 minutes for a Vdiff test, and around 3-10 minutes for a V/T test). Advantageously, because the self-diagnostic tests only require loads that are a fraction of the battery's capacity, the battery assembly 102 does not need to be taken offline during the tests. In some embodiments, the diagnostic tests are performed by discharging the batteries over a range of voltage values that are within the exponential region of the battery's discharge curve.

Referring to FIG. 1, the battery analysis system 100 may include a battery assembly 102, a relay 104, a battery management system 105, a control board 110, a first load control board 120, and a second load control board 130. In some embodiments, the battery assembly 102 comprises at least one rechargeable battery. In some embodiments, the battery assembly 102 comprises multiple rechargeable batteries that are arranged in a string or a stack. In some embodiments, a respective battery of the battery assembly 102 can have a capacity of up to 400 Ah, 500 Ah, 1000 Ah, or over 1000 Ah. In some embodiments, the battery assembly 102 comprises a plurality of battery assemblies 102. The battery assemblies 102 may include one or more cells. For example, the cells may be based on a Lithium Ion chemistry (e.g., LiFePO₄). Cells may be arranged in a stack (e.g., series, parallel) to produce a desired voltage or current output. The battery analysis system 100 includes circuitry that connects to one or more of the cells, and configured to enable charging, discharging, monitoring, or a combination thereof. The battery analysis system 100 may be associated with bus bars or switches (e.g., transistors or other types of switches) to control the flow of electricity between the battery assembly 102 and a power system 103 (e.g., a load, a charger, or a combination thereof) or another battery assembly. For example, the battery assemblies 102 may be daisy-chained, or arranged in series, with other battery assemblies due to the current throughput of the bus bars. The bus bars may be arranged to keep currents off of the control board 110, the first load control board 120, and/or the second load control board 130, allowing for higher currents.

The power system 103 may comprise an external power system for supplying power to one or more external systems, devices, components, and the like. In addition, the power system 103 may provide power to the battery assembly 102 for maintaining a charge level of the battery assembly 102. As an example, the battery assembly 102 may be configured to operate as a back-up power supply to the one or more external systems, devices, components, and the like in the event of a power loss. The control board 110 may be configured to implement one or more diagnostic load tests of the battery assembly 102 in order to determine the state of health of the battery assembly 102.

The battery management system 105 may be configured to manage and/or monitor one or more battery assemblies (e.g., battery assembly 102). For example, the battery management system 105 can include circuitry that connects to one or more of the cells and enables charging, monitoring, or a combination thereof. In an example, the battery management system 105 may be included in the battery assembly 102 instead of external to the battery assembly 102 as shown in FIG. 1. The battery management system 105 may monitor the battery assembly 102 during one or more diagnostic load tests for determining state of health information of the battery assembly 102. For example, the battery management system 105 may monitor voltage, current, and cell temperature measurements/data of the battery assembly 102 during the one or more diagnostic load tests and provide voltage, current, and temperature readings to the control board 110 for further processing. In an example, the battery management system 105 may be configured to isolate the battery assembly 102 based on the voltage, current, and/or cell temperature data as a safety measure. For example, if one or more voltage values, current values, and/or temperature values exceed a threshold, the battery management system 105 may isolate the battery assembly 102 to prevent possible further damage to the battery assembly 102.

The control board 110 may comprise a circuit board that includes a controller 112 and/or one or more interfaces 114, for controlling the charging and monitoring of the battery assembly 102. The control board 110 may interface with the battery management system 105 for receiving the voltage, current, and cell temperature data/information of the battery assembly 102. In an example, the control board 110 may interface directly with the battery assembly 102 for receiving the voltage, current, and cell temperature data/information of the battery assembly 102. As an example, leads may connect individual cells of the battery assembly 102 to the circuit board and integrated circuitry of the circuit board of the control board 110. For example, the battery management system 105 and/or the interface 114 may include individual connections to the one or more cells of the battery assembly 102. The control board 110 may be powered via a power source 101. For example, the power source 101 may comprise a power supply such as a 24V, 10 A power supply. The controller 112 may comprise a microcontroller, a processor, and the like. The controller 112 may receive commands via the one or more interfaces 114 to enter into one or more operating modes such as a startup mode, a wakeup mode, a shutdown mode, a sleep mode, and/or other operating modes. In an example, the controller 112 may receive battery data (e.g., current, voltage, cell temperature, etc.) based on one or more diagnostic load tests via the one or more interfaces 114.

The controller 112 may be configured to implement one or more diagnostic load tests of the battery assembly 102 by controlling the first load control board 120 and/or the second load control board 130, to discharge the battery assembly 102 according to different load currents at different time points for different time durations. In accordance with some embodiments, the controller 112 is configured to implement (e.g., conduct) the one or more diagnostic load tests on the battery assembly 102 to determine a state of health of the battery assembly. The one or more diagnostic tests include one or more Vdiff tests and/or one or more V/T tests. The one or more diagnostic load tests can be executed automatically, at predetermined times (e.g., fortnightly, monthly, once every two months, quarterly, etc.). Automating battery surveillance and monitoring enhances safety and eliminates resources and maintenance cost.

The first load control board 120 may comprise a high current board. The second load control board 130 may comprise a constant/low current board. In some embodiments, the first load control board 120 represents a circuit that is configured to execute a Vdiff test. In some embodiments, the second load control board 130 represents a circuit that is configured to execute a V/T test. In some embodiments, the first load control board 120 and second load control board 130 can be implemented (e.g., combined) as a single load control board, such as load control board 140 as illustrated in FIG. 1.

The first load control board 120 may comprise a circuit board that includes at least a current control component 122, a switch component 124, a current sensor 126, and a load resistor 128 (e.g., a resistor assembly). In some embodiments, the load resistor 128 may be configured externally to the first load control board 120 instead of, or in addition to, being included in the first load control board 120 as shown in FIG. 1. In some embodiments, the current control component 122 may be configured to control the switch component 124 to switch a “high current” load (e.g., via the load resistor 128) on and off, based on one or more commands received from the controller 112. The high current load can be a load that is applied during a Vdiff test. In some embodiments, the load resistor 128 comprises one or more adjustable, variable resistors. In some embodiments, the load resistor 128 comprises one or more programmable resistors whose resistance values can be varied (e.g., adjusted) by control board 110.

In some embodiments, the controller 112 is configured to determine a resistor value to be applied (e.g., via load resistor 128) for the Vdiff test, so that it results in a load (e.g., a current drain, in amperes) that is around 8-12% of the load battery current capability (e.g., battery capacity, in ampere hours). As an example, the high current load can have a current value of anywhere from 4 A to 100 A, depending on the capacity of the battery assembly 102 (or the capacity of the batteries being tested). In an example, the controller 112 may be configured to control the switch component 124 to switch the high current load on and off. The switch component 124 may be configured to open and close a connection between the battery assembly 102 and the first load control board 120 to draw the high current from the battery assembly 102, via the load resistor 128, during the one or more diagnostic load tests. The switch component 124 may comprise transistors, switches, other implements, or combinations thereof. For example, the switch component 124 may comprise a solenoid-operated switch. The switch component 124 may comprise field-effect transistors (FETs) or metal-oxide-semiconductor field-effect transistors (MOSFETs). The current sensor 126 may be configured to determine a current flowing through a bus bar configured to connect the switch component 124 and/or the load resistor 128 to the battery assembly 102.

The second load control board 130 may comprise a circuit board that includes at least a current control component 132, a switch component 134, and one or more power resistors 136. In some embodiments, the one or more power resistors 136 comprise one or more variable resistors whose values can be controlled via control board 110. In some embodiments, the one or more power resistors 136 comprise one or more variable, programmable resistors whose values can be controlled via the controller 112. The current control component 132 may be configured to control the switch component 134 to switch a low/constant current load on and off. The low/constant current can be a current that is applied during a V/T test. In some embodiments, the controller 112 is configured to determine a resistor value to be applied (e.g., via the power resistors 136) for the V/T test, so as to provide a load (e.g., a current drain of the battery, expressed in amperes) that is around 1-3% of the load battery current capability (e.g., in ampere hours). As an example, the low/constant current can have a current value of up to 4 A, depending on the capacity of the battery assembly 102 (or the capacity of the batteries being tested). In an example, the controller 112 may be configured to control the switch component 132 to switch the low/constant current load on and off. The switch component 134 may be configured to open and close a connection between the battery assembly 102 and the second load control board 130 to draw the constant current from the battery assembly 102 during the one or more diagnostic load tests. The switch component 134 may comprise transistors, switches, other implements, or combinations thereof. For example, the switch component 134 may comprise a solenoid-operated switch. The switch component 134 may comprise field-effect transistors (FETs) or metal-oxide-semiconductor field-effect transistors (MOSFETs). The power resistors 136 may be configured to offload power requirements of the switch component 134. For example, at a current of 4 A, each power resistor 136 may generate 40 watts of power and each power resistor 136 may drop 10 VDC (e.g., 40 watts each).

The controller 112 may be configured to operate a relay 104 configured to impede or allow the flow of electrons from/to the battery assembly 102. For example, the relay 104 may be configured to open and close a connection between the battery assembly 102 and the power system 103. For example, the relay 104 disconnects the battery assembly 102 from the power system 103 during the diagnostic load tests. When the tests terminate (e.g., normally or in an emergency case), the relay 104 may de-energize and enter a closed state, and thus, reconnect the battery assembly 102 to the power system 103. The relay 104 may comprise transistors, switches, other implements, or combinations thereof. For example, the relay 104 may comprise a solenoid-operated switch. The relay 104 may comprise field-effect transistors (FETs) or metal-oxide-semiconductor field-effect transistors (MOSFETs).

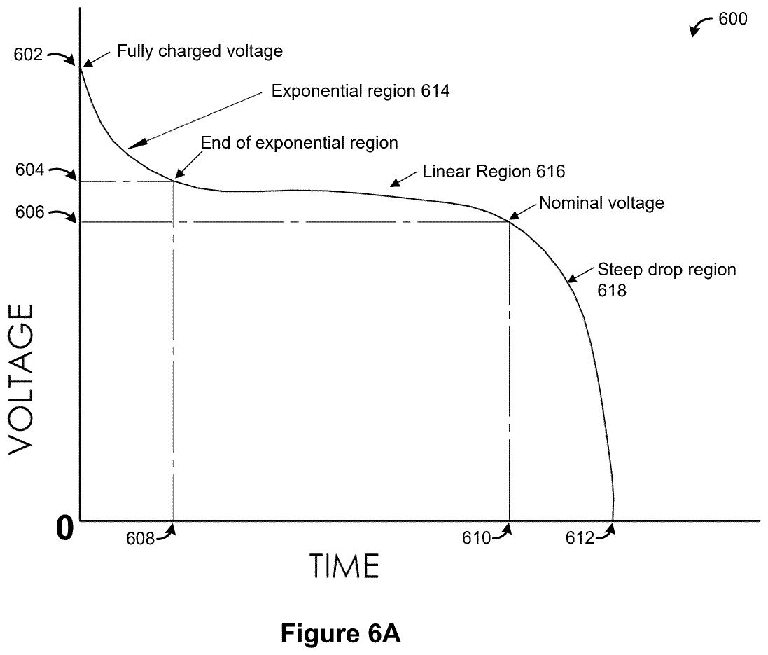

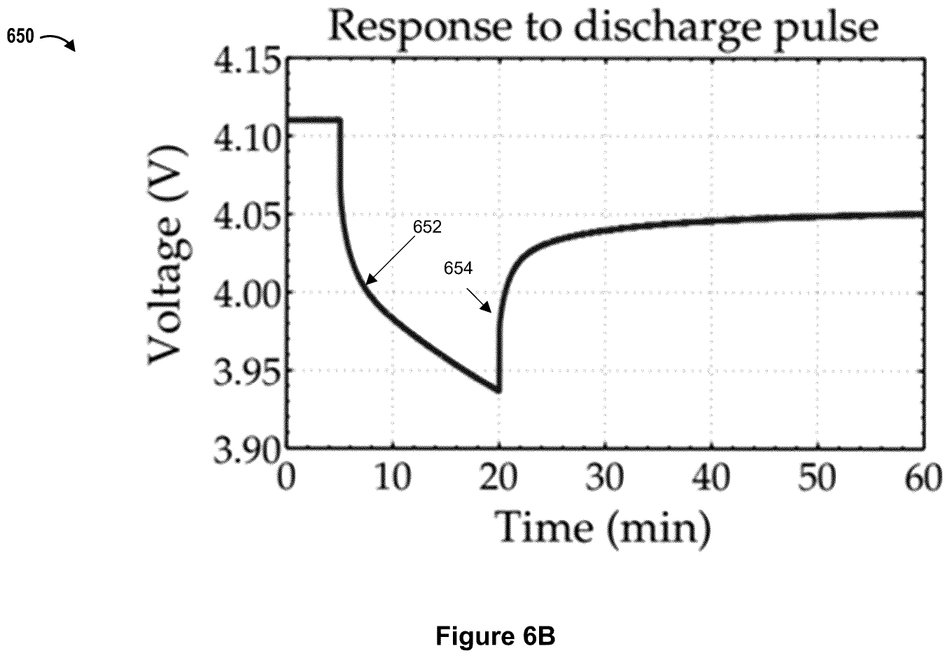

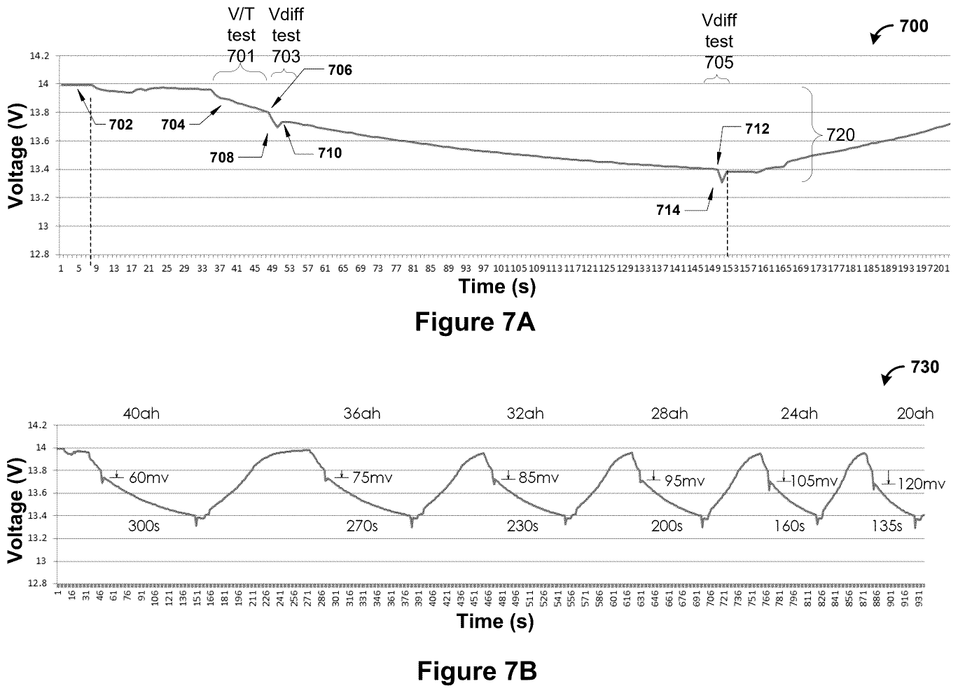

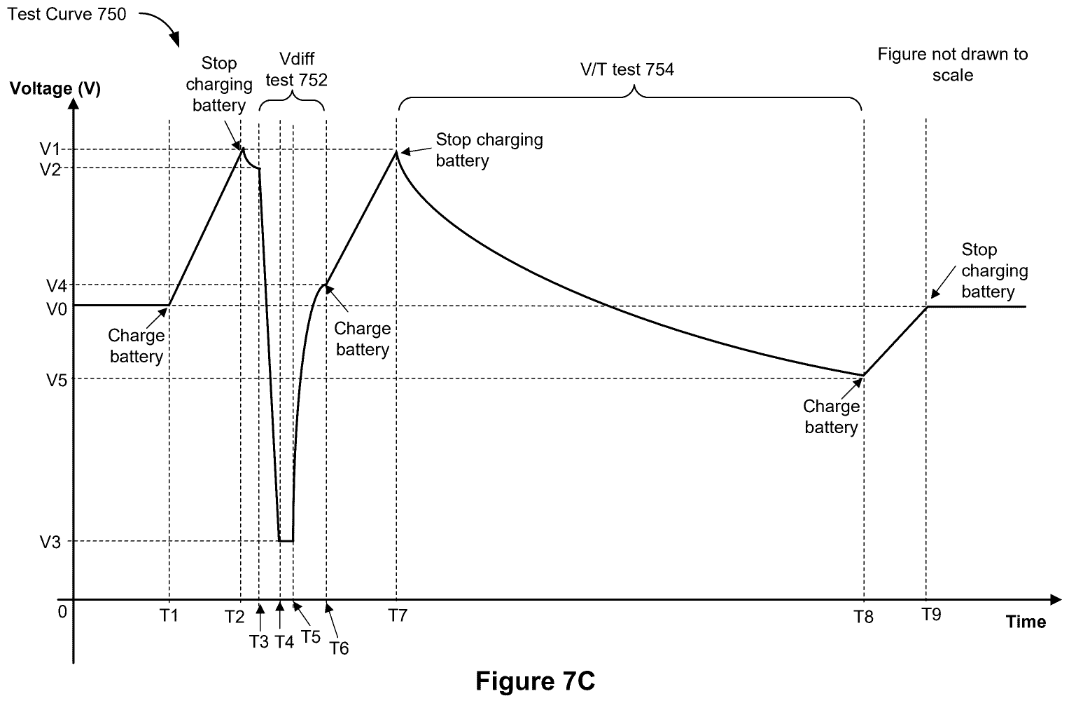

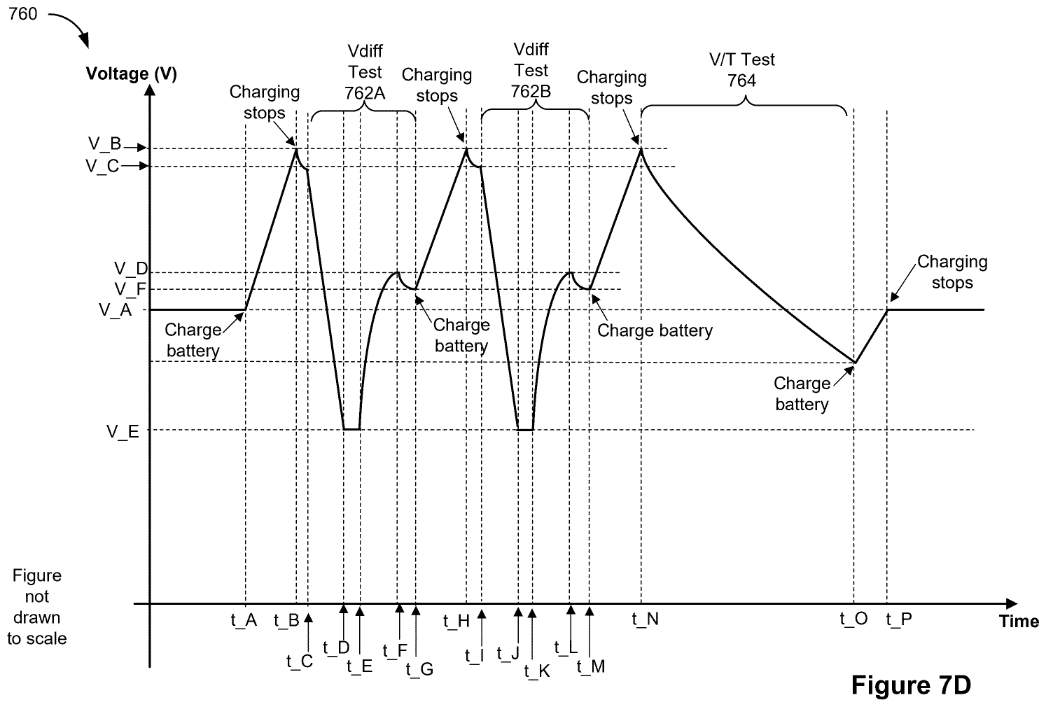

In one example, the one or more diagnostic load tests may comprise the first load control board 120, the second load control board 130, and/or the load control board 140 for initiating respective diagnostic load tests in sequence. In some embodiments, the respective diagnostic tests include a “high current” test, also known herein as an impulse discharge test or a Vdiff test. In some embodiments, the respective diagnostic tests include a “constant current” test, which is also referred to herein as a voltage over time test or a V/T test. In some embodiments, one or more Vdiff tests are performed before one or more V/T tests. In some embodiments, one or more V/T tests are performed before one or more Vdiff tests. In some embodiments, the diagnostic tests that are initiated in sequence include a first Vdiff test, followed by a V/T test, followed by a second Vdiff test. In some embodiments, the diagnostic tests that are initiated in sequence include a first V/T test, followed by a Vdiff test, followed by a second V/T test. In some embodiments, the diagnostic tests that are initiated in sequence include any combination of Vdiff and V/T tests and in any order. In some embodiments, the battery assembly 102 is recharged between tests. In some embodiments, the diagnostic load tests are performed in sequence, according to voltage values of the battery assembly 102 that correspond to those in the exponential region of the battery discharge curve (e.g., exponential region 614 in FIG. 6A), where the battery characteristics in this region are trendable and repeatable. FIGS. 7A, 7C, and 7D describe and illustrate example sequences of Vdiff and V/T tests.

With continued reference to FIG. 1, the control board 110 may receive a start test command (e.g., via a test switch or via an external computing device via the interface 114) in order to initiate the diagnostic load tests. The control board 110, via the interface 114 and/or the controller 112, may determine whether the power system 103 is supplying power, and that the battery assembly 102 is not providing power, to an external system, for example. If the power system 103 is providing power to the external system and the battery assembly 102 is not providing power to the external system (e.g. the battery assembly 102 is not in use), the controller 112 may cause the battery assembly 102 to disconnect (e.g., by opening the relay 104) from the power system 103. For example, the battery assembly 102 may initially receive power from the power system 103 to maintain a charge level (e.g., 100% capacity or charge level) of the battery assembly 102. While the battery assembly 102 is disconnected from the power system 103, the controller 112 may send a command to the first load control board 120 to cause the first load control board 120 to discharge the battery assembly 102 at a first time point for a first duration (e.g. several seconds) based on drawing a first current from the battery assembly 102. In some embodiments, the first current is determined according to a capacity of the battery assembly 102. In some embodiments, the first current corresponds to 8-12% of the load battery capacity (measured in Ah). Using a single battery as an example, if the battery cell is a 12V, 400 Ah battery, 10% of the load (current) is 40 Ah (i.e., 40 amps of current for one hour, or 4 amp for 10 hours, or 400 amps of current for 0.1 hour), and thus the resistor assembly 128 would apply a resistance of R=V/I=12/40=0.3 ohm (for one hour). For a string of battery cells that provides 480V, the resistor assembly 128 would apply a resistance of 480 V/40 A=12 ohms (for one hour). In some instances, the first current may have a value of around 4 A to 100 A. In some instances, the first current may have a value of around 4 A to 200 A. In some instances, the first current may have a value of around 4 A to 300 A. In some instances, the first current may have a value of around 4 A to 400 A.

For example, in some embodiments, the control board 110 may implement a Vdiff test (e.g., impulse discharge test) to draw the first current for the first duration in order to measure a starting voltage at the initiation of the Vdiff test and a second voltage after drawing the first current for the first duration. A resistor assembly 128 may be connected between the first load control board 120 and the relay 104 for drawing the high current from the battery assembly 102 for the Vdiff test. For example, the resistor assembly 128 may be energized via the first load control board 120 to Vdiff test the battery assembly 102. The resistor assembly 128 may comprise a load resistor bank. After the first duration, the controller 112 may cause the battery assembly 102 to reconnect (e.g., via closing the relay 104) to the power system 103 to recharge the battery assembly 102. After the battery assembly 102 is recharged, the controller 112 may send a command to the second load control board 130 to cause the second load control board 130 to discharge the battery assembly 102 at a second time point for a second duration (e.g., several minutes) based on drawing a second current (e.g., up to 4 A) from the battery assembly 102. For example, the control board 110 may implement a constant current test to measure how long it takes the battery assembly 102 to go from a first voltage to a second voltage by monitoring the battery assembly 102 to determine when the battery assembly 102 reaches a threshold voltage (e.g., up to approximately 25 V) before causing the second load control board 130 to draw the second current from the battery assembly 102. After the second duration, the controller 112 may cause the battery assembly 102 to reconnect to the power system 103 to recharge the battery assembly 102. The second duration (e.g., several minutes) may be greater than the first duration (e.g., several seconds). In an example, the controller 112 may cause the second load control board 130 to implement the V/T (e.g., constant current) test first, and then cause the first load control board 120 to implement the Vdiff test after the constant current test according to the process as described above.

It should be understood that the order/sequence of the diagnostic load tests as described above is merely one of many examples and is not considered to be exhaustive. The order/sequence of the diagnostic load tests may be fully configurable and may be implemented in any order/sequence. In an example, the control board 110 may be configured to automatically terminate the diagnostic load tests based on a detection of a loss of voltage to the control board 110 or a fault in, or a loss of power being received from, the power system 103 that causes the battery assembly 102 to activate and provide backup power (e.g., to an external system).

The control board 110 may be configured to continuously monitor battery data (e.g., current, voltage, cell temperature, etc.). For example, the control board 110 may continuously monitor (e.g., via the battery management system 105, a computing device, etc.) the battery data as the one or more diagnostic load tests are being implemented. For example, the control board 110 may determine one or more values associated with one or more parameters of the battery assembly 102 at one or more time points during the one or more diagnostic load tests. For example, the control board 110 may determine one or more first values prior to the discharge of the battery assembly 102 (e.g., when the battery is at full charge/capacity), one or more second values during the discharge of the battery assembly 102 via the first load control board 120, one or more third values after the battery is recharged after being discharged via the first load control board 120, one or more fourth values during the discharge of the battery assembly 102 via the second load control board 130, and one or more fifth values after the battery assembly is recharged after being discharged via the second load control board 130. The one or more parameters may comprise one or more of a discrete cell and assembly voltage of the battery assembly 102, a total power available of the battery assembly 102, a state of charge of the battery assembly 102, a temperature associated with the battery assembly 102, an amount of power discharged by the battery assembly 102, or an amount of power received by the battery assembly 102. The control board 110 may be configured to determine first state of health information of the battery assembly 102 based on the one or more first values, the one or more second values, and the one or more third values. For example, the control board 110 may determine (e.g., measure) a starting voltage at the initiation of the Vdiff test, a second voltage after the first load control board 120 draws the first current for the first duration, and a third voltage (e.g., a “spring back voltage”) after the first load control board 120 releases the load resistor 128 and stops drawing the first current. In addition, the control board may be configured to determine second state of health information of the battery assembly 102 based on the one or more third values, the one or more fourth values, and the one or more fifth values. For example, the control board 110 may determine (e.g., measure) a duration it takes for the monitored voltage to go from a first voltage to a second voltage during the constant current test. The control board 110 may then determine overall state of health of the battery assembly 102 based on the first state of health of information and the second state of health information. For example, the control board 110 may be configured to determine the first state of health information associated with the Vdiff test (e.g., high current test) and the second state of health information based on the constant/low current test (e.g., V/T test). The control board 110 may be configured to compare the first state of health information with the second state of health information to determine the overall state of health of the battery assembly 102. In an example, the control board 110 may be configured to output (e.g., send) the battery data (e.g., the one or more values) to an external computing device (e.g., a battery management system 105 or computing device), wherein the external computing device may process the one or more values to determine a state of health of the battery assembly 102.

In another example, the one or more diagnostic load tests may comprise implementing the constant current test (e.g., a low current test) by the second load control board 130 and then implementing the Vdiff test (e.g., a high current test) by the first load control board 120 during the constant current test. The control board 110 may receive a start test command (e.g., via a test switch or via an external computing device via the interface 114) in order to initiate the diagnostic load tests. The control board 110, via the interface 114 and/or the controller 112, may determine whether the power system 103 is supplying power, and that the battery assembly 102 is not providing power, to an external system, for example. If the power system 103 is providing power to the external system and the battery assembly 102 is not providing power to the external system, the controller 112 may cause the battery assembly 102 to disconnect from the power system 103. For example, the battery assembly 102 may initially receive power from the power system 103 to maintain a charge level (e.g., 100% capacity or charge level) of the battery assembly 102. While the battery assembly 102 is disconnected from the power system 103, the controller 112 may send a command to the second load control board 130 to cause the second load control board 130 to discharge the battery assembly 102 at a first time point for a first duration (e.g., several minutes) based on drawing a first current (e.g., low amp draw up to 4 A) from the battery assembly 102. The controller 112 may then send a command to the first load control board 120 to cause the first load control board 120 to cause the first load control board 120 to discharge the battery assembly 102 at a second time point for a second duration (e.g., few seconds) based on drawing a second current (e.g., a high amp draw between 4 A to 100 A) from the battery assembly 102. For example, while the second load control board 130 is discharging the battery according to the first current for the first duration, the first load control board 120 may implement the Vdiff test based on drawing the second current for the second duration. In an example, the controller 112 may send commands, at several time points during the constant current test via the second load control board 130, to the first load control board 120 to initiate the Vdiff test and cause the first load control board 120 to draw the second current for the second duration at each time point. After the first duration, the controller 112 may cause the relay 104 to reconnect the battery assembly 102 to the power system 103. As an example, the battery assembly 102 may be recharged based on the reconnection to the power system 103. In an example, the control board 110 may be configured to automatically terminate the diagnostic load tests based on a detection of a loss of voltage to the control board 110 or a fault in, or a loss of power being received from, the power system 103 that causes the battery assembly 102 to activate and provide backup power (e.g., to an external system).

The control board 110 may be configured to receive battery data (e.g., via the battery management system 105, a computing device, etc.) during the one or more diagnostic load tests. For example, the control board 110 may determine one or more values associated with the one or more parameters of the battery assembly 102 at one or more time points during the one or more diagnostic load tests. The one or more time points may comprise one or more of a time point prior to the discharge of the battery assembly 102 via the second load control board 130, a time point during/after the discharge of the battery assembly 102 via the second load control board 130, a time point during/after the discharge of the battery assembly 102 via the first load control board 120, or a time point after the reconnection of the battery assembly 102 to the power system 103. The control board 110 may be configured to process the one or more values to determine a state of health of the battery assembly 102. In an example, the control board 110 may be configured to output (e.g., send) the battery data (e.g., the one or more values) to an external computing device (e.g., a battery management system 105 or computing device), wherein the external computing device may process the one or more values to determine a state of health of the battery assembly 102.

Although FIG. 1 shows first load control board 120 and second load control board 130 as separate control boards, in some embodiments, in some embodiments first load control board 120 and second load control board 130 can be implemented (e.g., combined) as a single load control board, such as load control board 140 as illustrated in FIG. 1. For example, in some embodiments, load control board 140 is configured to perform both the Vdiff and V/T tests disclosed herein. In some embodiments, control board 110 is located within the same enclosure as the battery assembly 102. In some embodiments, control board 110 is located within the same enclosure as load control boards 120, 130, and/or 140. In some embodiments, load control boards 120, 130, and/or 140 are located within the same enclosure as the battery assembly 102. In some embodiments, control board 110, load control boards 120, 130, and/or 140 and battery assembly 102 are all located within the same enclosure.

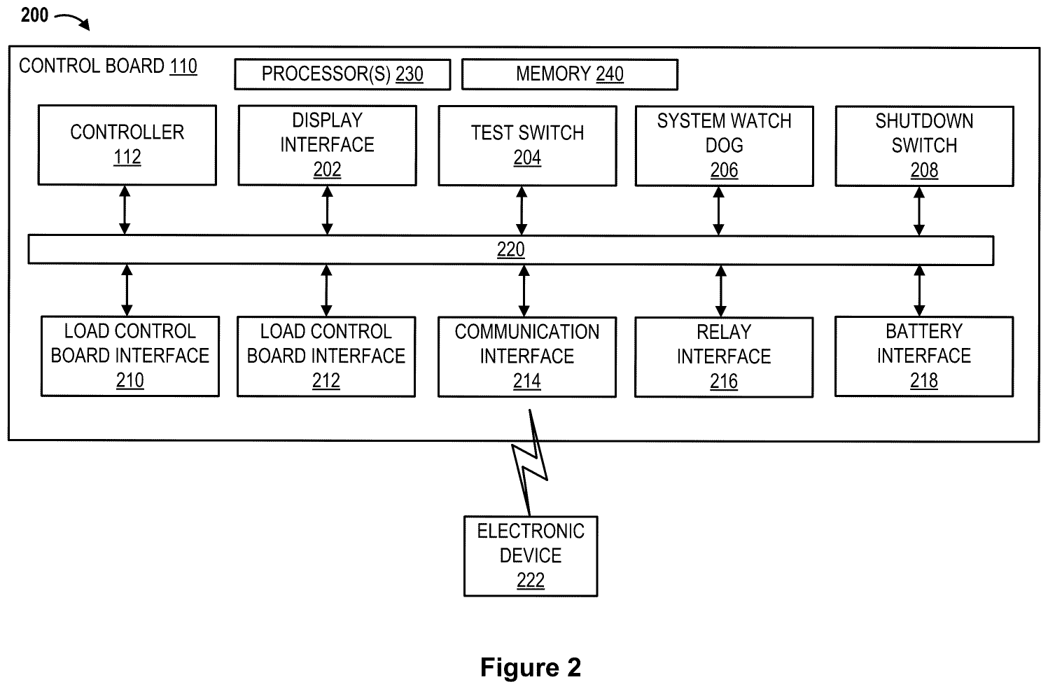

FIG. 2 shows an example control board configuration 200 (e.g., control board 110). The control board 110 may comprise a circuit board that includes one or more processors 230, memory 240, a controller 112, a display interface 202, a test switch 204, a system watch dog 206, a shutdown switch 208, a first load control board interface 210, a second load control board interface 212, a communication interface 214, a relay interface 216, a battery interface 218, and/or one or more traces/leads 220. The traces/leads 220 may be conductive elements etched into the circuit board (e.g., control board 110) or other wiring associated with the circuit board. The controller 112, the display interface 202, the test switch 204, the system watch dog 206, the shutdown switch 208, the first load control board interface 210, the second load control board interface 212, the communication interface 214, the relay interface 216, and the battery interface 218 may be communicatively connected via the one or more traces/leads 220 of the circuit board. The memory 240 stores instructions that are configured to be executed by the one or more processors 230.

The controller 112 may comprise a microcontroller unit (MCU) that may include a memory (e.g., memory 240) and a Central Processing Unit (CPU) (e.g., processor(s) 230), an Application Processor (AP), or a Communication Processor (CP). The controller 112 may execute processor-executable instructions to control at least one of the display interface 202, the first load control board interface 210, the second load control board interface 212, the communication interface 214, the relay interface 216, and the battery interface 218 via the one or more traces/leads 220 of the circuit board. The processor-executable instructions executed by the controller 112 may be stored and/or maintained by the memory. The memory may include a volatile and/or non-volatile memory. The memory may include random-access memory (RAM), flash memory, or any combination thereof. The memory may store, for example, a command or data associated with at least one of the display interface 202, the test switch 204, the system watch dog 206, the shutdown switch 208, the first load control board interface 210, the second load control board interface 212, the communication interface 214, the relay interface 216, and/or the battery interface 218 of the control board 110. According to various examples, the memory may store software and/or a program or may comprise firmware. For example, the program may include a kernel, a middleware, an Application Programming Interface (API), an application program, and/or the like, configured for controlling one or more functions of the control board 110. The memory may include a computer-readable recording medium (e.g., a non-transitory computer-readable medium) having a program recorded therein to perform the methods according to various embodiments by the controller 112.

The kernel may control or manage, for example, system resources used to execute an operation or function implemented in other programs (e.g., the middleware, the API, or the application program). Further, the kernel may provide an interface capable of controlling or managing the system resources by accessing individual elements of the controller 112 in the middleware, the API, or the application program. The middleware may perform, for example, a mediation role, so that the API, and/or the application program can communicate with the kernel to exchange data. Further, the middleware may handle one or more task requests received from the application program according to a priority. For example, the middleware may assign a priority of using the system resources of the control board 110 to the application program. For example, the middleware may process the one or more task requests according to the priority assigned to the application program, and thus, may perform scheduling or load balancing on the one or more task requests. The API may include at least one interface or function (e.g., instruction), for example, for file control, window control, video processing, and/or character control, as an interface capable of controlling a function provided by the application program in the kernel or the middleware. The application program may be configured to implement the one or more diagnostic load tests.

The display interface 202 may be configured to output the battery data to a display device, for example. For example, the display interface 202 may output the one or more parameters of the battery assembly 102 based on the one or more diagnostic load tests. The display interface 202 may output one or more of a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly.

The test switch 204 may be configured to initiate the one or more diagnostic load tests. For example, the test switch 204 may comprise a push button switch, a toggle switch, a tactile switch, and the like. Based on an activation of the switch (e.g., pressing a push button, toggling a switch, interacting with a tactile switch, etc.) the control board 110 may implement the one or more diagnostic load tests by causing the first load control board 120 and the second load control board 130 to apply one or more loads (e.g., high current load and/or a constant/low current load) to the battery assembly 102.

The system watch dog 206 may be configured to cause the relay 104 to power down and reconnect the battery assembly 102 to the power system 103. For example, the system watch dog 206 may be configured to require a signal from the controller 112 at a time interval (e.g., every 100 milliseconds (ms), 250 ms, 500 ms, etc.). In some embodiments, if the system watch dog 206 does not receive the signal from the controller 112, the system watch dog 206 may trigger the relay 104 to power down and reconnect the battery assembly 102 to the power system 103.

The shutdown switch 208 may be configured to terminate the one or more diagnostic load tests when the shutdown switch 208 is activated. For example, the shutdown switch 208 may comprise a push button switch, a toggle switch, a tactile switch, and the like. The shutdown switch 208 may be configured to activate based on pressing a push button, toggling a switch, interacting with a tactile switch, etc. In addition, the shutdown switch 208 may be configured to activate based on detection of a loss of voltage to the control board 110.

The current board interfaces 210, 212 may be configured to interface with the current boards 120, 130. The controller 112 may output commands to the current boards 120, 130 to implement the one or more diagnostic load tests (e.g., high current test and/or constant/low current test) via the current board interfaces 210, 212, respectively.

In one example, the controller 112 may cause the first load control board 120, via the first load control board interface 210, and the second load control board 130, via the second load control board interface 212, to initiate respective diagnostic load tests (e.g., high current test and constant current test) in sequence, wherein the battery assembly 102 is recharged between tests. The control board 110 may receive a start test command (e.g., via a test switch or via an external computing device via communication interface 214) in order to initiate the diagnostic load tests. The control board 110, via the communication interface 214 and/or the controller 112, may determine whether the power system 103 is supplying power, and that the battery assembly 102 is not providing power, to an external system, for example. If the power system 103 is providing power to the external system and the battery assembly 102 is not providing power to the external system (e.g. the battery assembly 102 is not in use), the controller 112 may cause the battery assembly 102 to disconnect (e.g., by opening the relay 104) from the power system 103. For example, the battery assembly 102 may initially receive power from the power system 103 to maintain a charge level (e.g., 100% capacity or charge level) of the battery assembly 102. While the battery assembly 102 is disconnected from the power system 103, the controller 112 may send a command, via the first load control board interface 210, to the first load control board 120 to cause the first load control board 120 to discharge the battery assembly 102 at a first time point for a first duration (e.g. several seconds) based on drawing a first current (e.g., 8-12% of the total capacity of the battery assembly) from the battery assembly 102. For example, the control board 110 may implement a Vdiff test to draw the first current for the first duration in order to measure a starting voltage at the initiation of the Vdiff test and a second voltage after drawing the first current for the first duration. A resistor assembly 128 may be connected between the first load control board 120 and the relay 104 for drawing the high current from the battery assembly 102 for the Vdiff test. For example, the resistor assembly 128 may be energized via the first load control board 120 to Vdiff test the battery assembly 102. The resistor assembly 128 may comprise a load resistor bank. After the first duration, the controller 112 may cause the battery assembly 102 to reconnect (e.g., via closing the relay 104) to the power system 103 to recharge the battery assembly 102. After the battery assembly 102 is recharged, the controller 112 may send a command, via the second load control board interface 212, to the second load control board 130 to cause the second load control board 130 to discharge the battery assembly 102 at a second time point for a second duration (e.g., several minutes) based on drawing a second current (e.g., up to 4 A) from the battery assembly 102. For example, the control board 110 may implement a constant current test to measure how long it takes the battery assembly 102 to go from a first voltage to a second voltage by monitoring, via the battery interface 218, the battery assembly 102 to determine when the battery assembly 102 reaches a threshold voltage (e.g., up to approximately 25 V) before causing the second load control board 130 to draw the second current from the battery assembly 102. After the second duration, the controller 112 may cause the battery assembly 102 to reconnect to the power system 103 to recharge the battery assembly 102. The second duration (e.g., several minutes) may be greater than the first duration (e.g., several seconds). In an example, the controller 112 may cause the second load control board 130 to implement the constant current test first and then cause the first load control board 120 to implement the Vdiff test second according to the process as described above.

It should be understood that the order/sequence of the diagnostic load tests as described above is merely one of many examples and is not considered to be exhaustive. The order/sequence of the diagnostic load tests may be fully configurable and may be implemented in any order/sequence. In an example, the control board 110 may be configured to automatically terminate the diagnostic load tests based on a detection of a loss of voltage to the control board 110 or a fault in, or a loss of power being received from, the power system 103 that causes the battery assembly 102 to activate and provide backup power (e.g., to an external system). Further, the diagnostic load tests are configurable to accommodate any battery capacity, by tuning respective values of the load resistor 128 and/or power resistors 136 according to the capacity of the battery assembly 102 that is being tested. In some embodiments, a respective battery of the battery assembly 102 can have a capacity of up to 400 Ah, 500 Ah, 1000 Ah, or over 1000 Ah. In some embodiments, the battery assembly 102 one or more stacks/strings of batteries, where a respective stack/string of batteries include one or more respective batteries.

In another example, the controller 112 may cause the second load control board 130, via the second load control board interface 212, to implement a constant current test (e.g., via a lower current draw) and the first load control board 120, via the first load control board interface 210, to implement a Vdiff test (e.g., by drawing a higher current during the constant current test. The control board 110 may receive a start test command (e.g., via a test switch or via an external computing device via the communication interface 214) in order to initiate the diagnostic load tests. The control board 110, via the communication interface 214 and/or the controller 112, may determine whether the power system 103 is supplying power, and that the battery assembly 102 is not providing power, to an external system, for example. If the power system 103 is providing power to the external system and the battery assembly 102 is not providing power to the external system, the controller 112 may cause the battery assembly 102 to disconnect from the power system 103. For example, the battery assembly 102 may initially receive power from the power system 103 to maintain a charge level (e.g., 100% capacity or charge level) of the battery assembly 102. While the battery assembly 102 is disconnected from the power system 103, the controller 112 may send a command, via the second load control board interface 212, to the second load control board 130 to cause the second load control board 130 to discharge the battery assembly 102 at a first time point for a first duration (e.g., several minutes) based on drawing a first current (e.g., low current value draw, for example up to 4 A) from the battery assembly 102. The controller 112 may then send a command to the first load control board 120 to cause the first load control board 120 to cause the first load control board 120 to discharge the battery assembly 102 at a second time point for a second duration (e.g., few seconds) based on drawing a second current (e.g., a high current value draw, for example between 4 A to 100 A) from the battery assembly 102. For example, while the second load control board 130 is discharging the battery according to the first current for the first duration, the first load control board 120 may implement the Vdiff test based on drawing the second current for the second duration. In an example, the controller 112 may send commands, at several time points during the constant current test via the second load control board 130, to the first load control board 120 to initiate the Vdiff test and cause the first load control board 120 to draw the second current for the second duration at each time point. After the first duration, the controller 112 may cause the relay 104, via the relay interface 216, to reconnect the battery assembly 102 to the power system 103. As an example, the battery assembly 102 may be recharged based on the reconnection to the power system 103. In an example, the control board 110 may be configured to automatically terminate the diagnostic load tests based on a detection of a loss of voltage to the control board 110 or a fault in, or a loss of power being received from, the power system 103 that causes the battery assembly 102 to activate and provide backup power (e.g., to an external system).

The communication interface 214 may be configured to receive one or more commands from an external device (e.g., electronic device 222, battery management system/device, etc.) for programming the controller 112 and/or for receiving battery data from the external device. For example, the external device may program the controller 112 to implement the one or more diagnostic load tests (e.g., high current test, constant/low current test, and/or any combinations thereof). In an example, the control board 110 may be configured to receive and process all or part of the battery data (e.g., one or more values associated with one or more of the parameters) from the external device. In an example, the control board 110 may be configured to output all or art of the battery data to the external device for further processing. For example, the external device may receive the battery data and determine the state of health of the battery assembly 102 based on the battery data.

The relay interface 216 may be configured to output commands from the controller 112 to the relay 104. For example, the controller 112 may be configured to send commands, via the relay interface 216 to cause the relay 104 to impede or allow the flow of electrons from/to the battery assembly 102. For example, the relay 104 may be configured to connect and disconnect the battery assembly 102 to the power system 103. The controller 112 may cause, via the relay interface 216, the relay 104 to disconnect the battery assembly 102 from the power system 103 during the diagnostic load tests. When the tests terminate (e.g., normally or in an emergency case), the controller 112 may cause, via the relay interface 216, the relay 104 to de-energize and enter a closed state, and thus, reconnect the battery assembly 102 to the power system 103.

The control board 110 may be configured to receive part or all of the battery data from the battery assembly 102 via the battery interface 218. For example, the battery interface 218 may comprise an I2C interface for receiving the battery data from the battery assembly 102 (e.g., via the batter management system 105). For example, the battery interface 218 may include circuitry that connects to one or more cells of the battery assembly 102. In an example, the battery interface 218 may interface with the battery management system 105 that includes circuitry that connects to one or more cells of the battery assembly 102. For example, the battery interface 218 and/or the battery management system 105 may include individual connections to the one or more cells. The cells may be connected in series. In an example, the battery interface 218 and/or the battery management system 105 may be configured to enable daisy chaining multiple control boards 110 together to test multiple battery assemblies 102. The battery interface 218 and/or the battery management system 105 may be configured to read battery voltage of the battery assembly 102. For example, the battery interface 218 and/or the battery management system 105 may be configured to read VCELL (e.g., single cell voltage), VTTL (e.g., total bank voltage) values associated with the battery assembly (e.g., during the one or more diagnostic load tests).

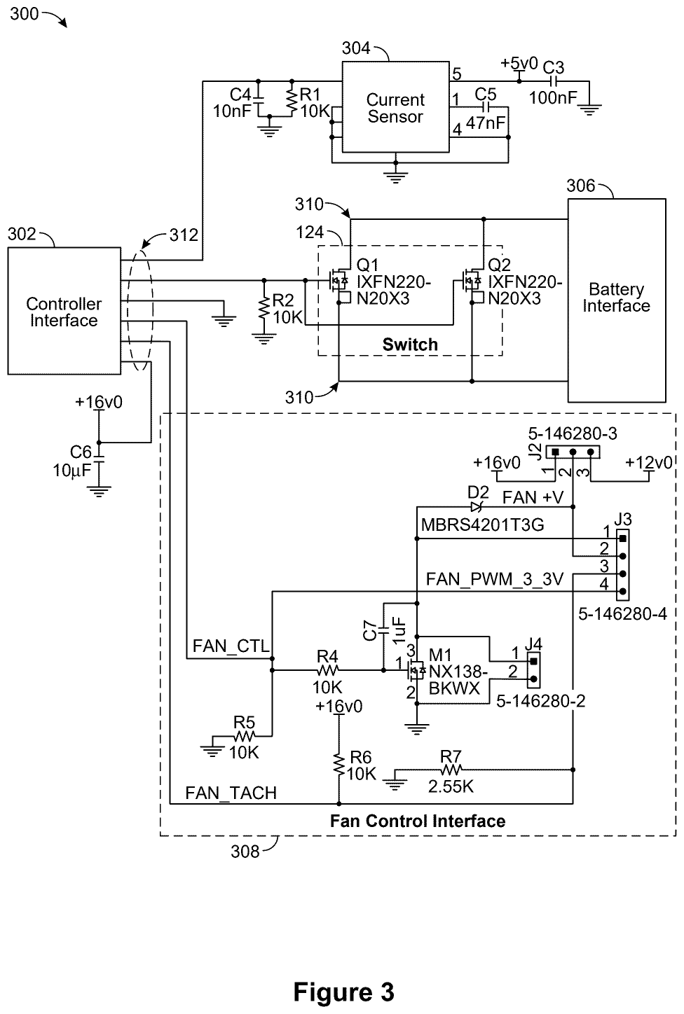

FIG. 3 shows an example circuitry of the first load control board 120. The first load control board 120 may comprise a high current load control board configured to apply a load to the battery assembly 102 by drawing a high current (e.g., 4 A to 100 A) from the battery assembly 102 for a duration (e.g., several seconds). The first load control board 120 may comprise a circuit board that includes at least a switch 124, a controller interface 302, a current sensor 304 (e.g., current sensor 126), a battery interface 306, a fan control interface 308, one or more bus bars 310, and one or more traces/leads 312. The traces/leads 312 may comprise conductive elements etched into the circuit board of the first load control board 120 or other wiring associated with the circuit board of the first load control board 120. The switch 124, the controller interface 302, the current sensor 304, the battery interface 306, and/or the fan control interface 308 may be communicatively coupled via the one or more traces/leads 312, as shown in FIG. 3, for example. The first load control board 120 may be configured to receive commands to implement the Vdiff test (e.g., high current test) via the controller interface 302. For example, the switch 124 may be configured to open and close a connection between the battery assembly 102 and the first load control board 120 to draw the high current from battery assembly 102 during the Vdiff test based on one or more commands from the controller 112 via the controller interface 302. The switch 124 may comprise transistors, switches, other implements, or combinations thereof. For example, the switch 124 may comprise a solenoid-operated switch. The switch 124 may comprise field-effect transistors (FETs) or metal-oxide-semiconductor field-effect transistors (MOSFETs). The current sensor 304 may be configured to determine a current flowing through the bus bars 310 configured to connect the switch 124 to the battery interface 306. The battery interface 306 may be connected to the battery assembly 102 for drawing the high current (e.g., corresponding to a load that is around 8-12% of the capacity of the battery assembly) from the battery assembly 102. In some instances, the high current can be about 4 A to 100 A, depending on the capacity of the battery assembly 102. The bus bar 310 may be configured to handle the high current drawn from the battery assembly 102. For example, the bus bar 310 may be configured to carry the current from the battery assembly 102 directly to the switch 124 (e.g., one or more high current MOSFETs). For example, the bus bars 310 may comprise conductive materials (e.g., copper, silver, gold, etc.), alloys, or combinations thereof. The fan control interface 308 may be configured to control a cooling fan of the control board 110. For example, the fan control interface 308 may be configured to control a fan rotation and check a fan speed of the cooling fan.

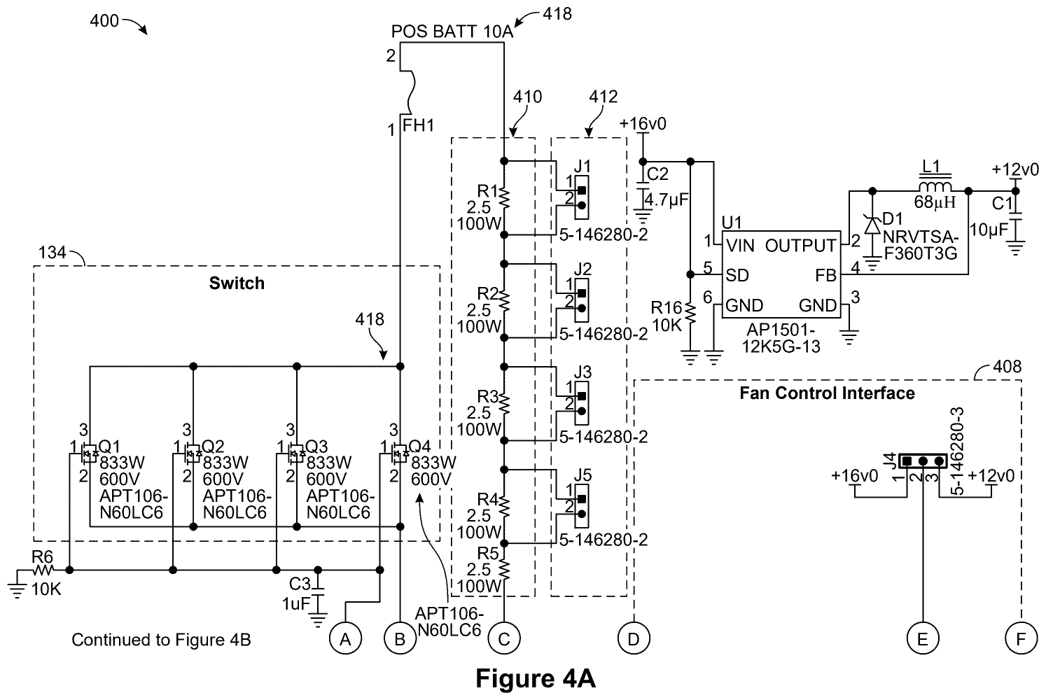

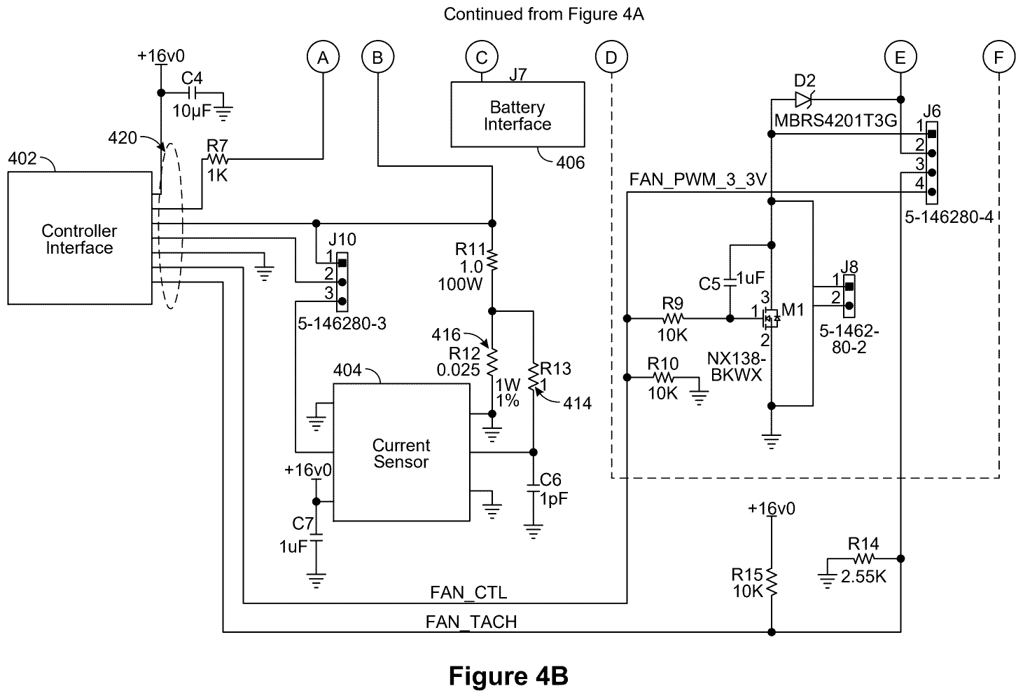

FIGS. 4A and 4B show an example circuitry of the second load control board 130, in accordance with some embodiments. The second load control board 130 may comprise a constant/low current load control board configured to apply a load to the battery assembly 102 by drawing a constant/low current from the battery assembly 102 for a duration of about several minutes. In some embodiments, the constant current is determined (e.g., by the control board 110) according to a capacity of the battery assembly 102. For example, the control board 110 is configured to determine a resistor value in the second load control board 130 such that the second load control board 130 provides a constant load that is around 1-3% of the load battery current capability (e.g., in Ah) In some embodiments, the constant/low current can be up to 4 A. The second load control board 130 may comprise a circuit board that includes at least a switch 134, a controller interface 402, a current sensor 404, a battery interface 406, a fan control interface 408, one or more power resistors 410 (e.g., power resistors 136), one or more bypass jumpers 412, a first current resistor 414, a second current resistor 416, one or more bus bars 418, and one or more traces/leads 420. The traces/leads 420 may comprise conductive elements etched into the circuit board of the second load control board 130 or other wiring associated with the circuit board of the second load control board 130. The switch 134, the controller interface 402, the current sensor 404, the battery interface 406, the fan control interface 408, the one or more power resistors 410 (e.g., power resistors 136), the one or more bypass jumpers 412, the first current resistor 414, and/or the second current resistor 416 may be communicatively coupled via the one or more traces/leads 420, as shown in FIG. 4, for example. The second load control board 130 may be configured to receive commands to implement the constant/low current test via the controller interface 402. For example, the switch 134 may be configured to open and close a connection between the battery assembly 102 and the second load control board 130 to draw the constant/low current from battery assembly 102 during the one or more diagnostic load tests based on one or more commands from the controller 112 via the controller interface 402. The switch 134 may comprise transistors, switches, other implements, or combinations thereof. For example, the switch 134 may comprise a solenoid-operated switch. The switch 134 may comprise field-effect transistors (FETs) or metal-oxide-semiconductor field-effect transistors (MOSFETs). The current sensor 404 may be configured to determine a current flowing through the bus bars 418 configured to connect the switch 134 to the battery interface 406. The battery interface 406 may be connected to the battery assembly 102 for drawing the constant/low current (e.g., up to 4 A) from the battery assembly 102. The one or more power resistors 410 may be configured to offload power requirements of the switch 134. For example, at 4 A, each power resistor 410 may generate 40 watts of power and each power resistor 410 may drop 10 VDC (e.g., 40 watts each). In an example, one or more of the power resistors 410 may be bypassed based on a battery voltage (e.g., below 50 VDC) of the connected battery assembly 102. For example, one or more of the bypass jumpers 412 may be configured for bypassing the one or more power resistors 410. The first current resistor 414 may be used by the current sensor 404 for detecting the current (e.g., over current detection). In an example, if the detected current is above 5 A, the constant/low current test may be triggered to terminate. The second current resistor 416 may be used for feedback for constant current control between the second load control board 130 and the control board 110. The bus bar 418 may be configured to handle a high current drawn from the battery assembly 102. For example, the bus bar 310 may be configured to carry the current from the battery assembly 102 directly to the switch 134 (e.g., one or more high current MOSFETs). For example, the bus bars 418 may comprise conductive materials (e.g., copper, silver, gold, etc.), alloys, or combinations thereof. The fan control interface 408 may be configured to control a cooling fan of the control board 110. For example, the fan control interface 408 may be configured to control a fan rotation and check a fan speed of the cooling fan. In an example, one or more heat sinks may be attached to the switch 134 (e.g., one or more high current MOSFETs) and/or the one or more power resistors 410.

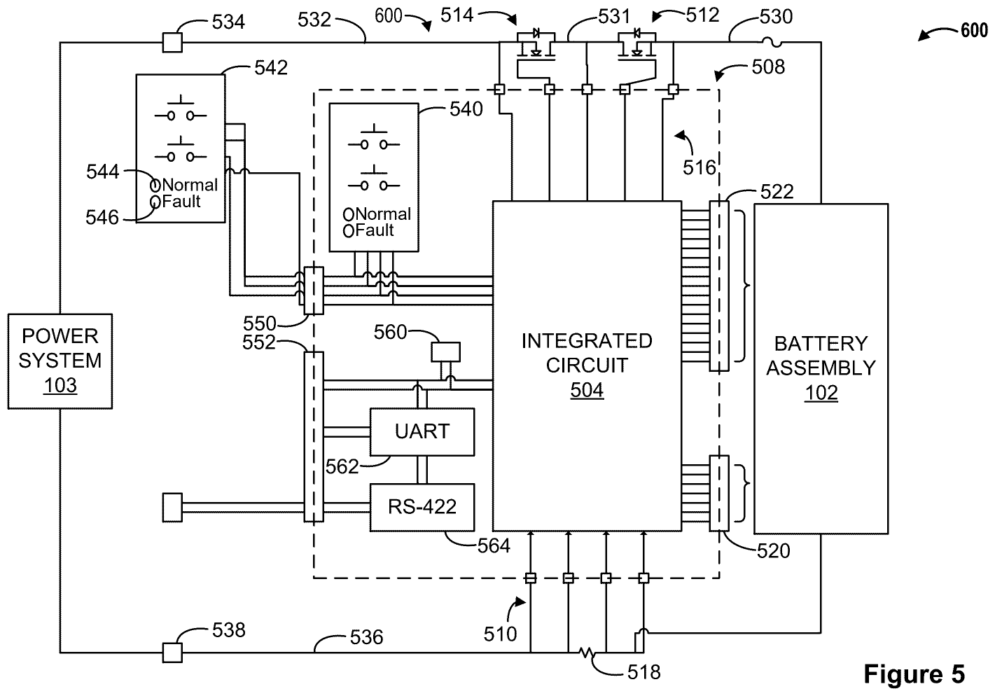

FIG. 5 shows an example battery management system 500 in accordance with one or more implementations of the present disclosure. As an example, the control board 110 may be configured to receive part or all of the battery data (e.g., one or more values associated with one or more of the parameters) from the battery management system 500 based on the one or more diagnostic load tests. The battery management system 500 may be configured to manage the battery assembly 102, or one or more battery assemblies 102, to ensure that the cells maintain balanced voltages and temperatures. For example, the battery management system 500 may include circuitry that connects to one or more of the cells and enables charging, monitoring, or a combination thereof. For example, the battery management system 500 may include individual connections 522 to the one or more cells. The cells may be connected in series. The battery management system 500 may include one or more integrated circuits 504 configured to monitor the battery assembly 102 or control operation of the battery assembly 102. For example, the integrated circuit 504 may include input and output pins for monitoring, charging, and discharging the cells of the battery assembly 102. The input and output pins may include a thermistor pin for measuring temperatures associated with the battery assembly 102. For example, circuitry may be included (e.g., thermistor connections 520) to monitor a temperature of the battery assembly 102.

The battery management system 500 may be associated with transistors, or other switches, to control the flow of electricity between the battery assembly 102 and a power system 103 (e.g., a load and/or a charger), or another battery assembly. For example, the battery assembly 102 may be daisy-chained, or arranged in series, with other battery assemblies due to the current throughput of one or more bus bars of the battery management system 500. The bus bars may be arranged to keep currents off of the circuit board 508, allowing for higher currents.

Further, the integrated circuit 504 may be associated with persistent programing, enabling operation without a microcontroller or processor. The integrated circuit 504 may be interacted with via a programming port 560. The programming port 560 may require a specific voltage, or voltage range, in order to enable programming. The voltage range may be different from a typical voltage range of the battery assembly 102. For example, in some embodiments, the voltage range of the battery assembly 102 may be 100-200 V DC, 150-200 V DC, 100-300 V DC, 100-400 V DC, 100-500 V DC, or 100-1000 V DC. The programming port may be enabled by application of a voltage of 10-12 Volts.

Integrated circuits (e.g., integrated circuit 504) may be designed for operation in combination with a microcontroller. For example, the microcontroller may be configured to control or monitor the integrated circuit 504 to ensure proper functionality and power consumption. For example, the microcontroller may send commands to the integrated circuit 504 to cause the circuit 504 to enter into one or more operating modes such as startup, wakeup, shutdown, sleep, and other operating modes. The microcontroller may also receive information from the integrated circuit 504 regarding the status of the battery assembly 102. For example, the microcontroller may receive the battery data (e.g., state of charge, temperature information, etc.) from the integrated circuit 504.

The combination of a microcontrollers and integrated circuits may introduce security vulnerabilities to the battery management system 500. For example, the microcontroller commands may be spoofed or intercepted to reprogram the integrated circuit 504 or to change battery assembly control or monitoring. As such, the microcontroller may be removed to increase security and remove necessary functionality. For example, the ability to change the modes of operation of the integrated circuit 504 may be unavailable without another interface for interacting with the integrated circuit 504.

The integrated circuit 504 may be disposed on a circuit board (e.g., circuit board 508). The circuit board may include connectors and interfaces for controlling and monitoring the battery assembly 102. For example, leads may connect the individual cells of the battery assembly 102 to the circuit board and the integrated circuitry. Thermistors may be connected with the integrated circuit 504 via connectors. The connectors may be soldered together with traces/leads on the circuit board that lead to the integrated circuit 504. The traces/leads may be conductive elements etched into the circuit board 508 or other wiring associated with the circuit board 508.

The battery management system 500 may include a programming port 560. The programming port 560 may include an interface for programming the integrated circuit 504. For example, the programming port 560 may require a programming voltage (e.g., 10-12 Volts) different from the typical voltage of the battery assembly 102. The programming port 560 may be an I2C header.

A universal asynchronous receiver-transmitter (UART) converter 562 may be configured to interface with the integrated circuit 504. For example, the UART converter 162 may convert UART protocol communications to I2C protocol communications for communications off-board. For example, the UART converter 562 may be interconnected with an RS-422 converter 564 or another type of port for communications off-board. For example, the integrated circuit 504 may provide information (e.g., the battery data) related to a battery state or a battery health of the battery assembly 102. For example, the information may be aggregated from multiple battery management systems to determine battery performance or maintenance needs. The integrated circuit 504 may be in communication with one or more indicators (e.g., indicators 540, 542). The indicators 540, 542 may provide an indication of normal operation and fault conditions that are perceivable by an operator (e.g., illumination of light-emitting diodes 544, 546). The UART connector may be connected to specific pins so that the RS-422 converter 564 cannot be used to program the one-time programmable memory or change other registers or memory of the integrated circuit 504.

The integrated circuit 504 may be associated with circuitry that can control the charging and discharging of the battery assembly 102. For example, the integrated circuit 504 may be configured to operate elements 512, 514 configured to impede or allow the flow of electrons from the battery assembly 102. Elements 512, 514 may be transistors, switches, other implements, or combinations thereof. For example, elements 512, 514 may include a solenoid-operated switch. The elements 512, 514 may be field-effect transistors (FETs) or metal-oxide-semiconductor field-effect transistors (MOSFETs). Elements 512, 514 may be interconnected via conductors 530, 531, 532. For example, conductors 530, 531, 532 may be bus bars (e.g., solid or woven conductors). The conductors 530, 531, 532 may be formed from conductive materials (e.g., copper, silver, gold), alloys, or combinations thereof. For example, the conductors 530, 531, 532 may be connected with the circuit board via traces/leads 516. For example, the traces/leads 516 may be configured to operate elements 512, 514 based on control signals from the integrated circuit 504 to control the flow of electricity via the conductors 530, 531, 532.

The integrated circuit 504 may be associated with one or more resistors (e.g., resistor 518). Resistor 518 may be associated with conductor 536. For example, resistor 518 may be a necked or narrowed portion of the conductor 536. The resistor 518 may be associated with the integrated circuit 504 via traces/leads 510. The conductors 532, 536 may be attached to the power system 503 via couplings 534, 538. Communications from the circuit board 508 may be facilitated via connectors 550, 552. A voltage drop across the resistor 518 or associated with the resistor 518 may be measured for coulomb counting. For example, discharge current from the battery assembly 102 may be monitored by measuring the voltage drop associated with the resistor 518. Further, charge current to the battery assembly 102 may be monitored by measuring the voltage drop associated with the resistor 518. In such a way, the integrated circuit 504 may be configured to monitor the state of charge, state of health, or other parameters (e.g., all or part of the battery data) of the battery assembly 102 and provide the data to the control board 110 for further processing. In an example, the resistor 518 may be omitted.

FIG. 6A illustrates an example battery discharge curve 600, in accordance with some embodiments. The battery discharge curve 600 includes an exponential region 614, which is the initial part of the discharge where the voltage of the battery drops rapidly. This is followed by a linear region 616, which exhibits a relatively linear decrease in voltage as the battery is discharged. Then, there is a final steep drop region 618 as the battery approaches full discharge

In some embodiments, the battery represented by the voltage curve 600 is a rechargeable battery, such as a nickel-cadmium (NiCad) battery, a nickel-metal hydride (NiMH), and a lithium ion based battery such as Lithium Ion Phosphate (LiFePo4) battery. A full voltage of the battery is indicated by the point 602. As an example, the full voltage of the battery can be 14.4 V. An exponential voltage value is indicated by the point 604. As an example, the exponential voltage value is 13.3 V. A nominal voltage is indicated by the point 606. As an example, the nominal voltage value is 12.5 V. Additionally, an exponential discharge time, a nominal discharge time, and a max discharge time are indicated by points 608, 610, and 612, respectively. In accordance with some embodiments, one or more diagnostic tests, such as one or more Vdiff tests and/or one or more V/T tests, are performed on a battery by obtaining a discharge curve corresponding to the battery and specifying (e.g., selecting) voltage values that lie within the exponential region 614 of the battery discharge curve 600. The diagnostic tests are performed using battery voltage values that lie within the exponential region 614 (e.g., voltage values ranging from point 604 to from 606) because of predictability of battery response characteristics in this region. Performing diagnostic tests according to voltage values that lie within the exponential region of the battery discharge curve can help in predicting battery health and battery life, optimizing charging and discharging strategies, and/or preventing over-discharge, which can damage the battery.

While an exemplary battery discharge curve 600 is provided, a person skilled in the art would appreciate that any battery discharge curve can be utilized. For example, battery manufacturers publish battery discharge curves for different cell types, ampacity, temperature, lifetime cycle count, etc. A lifetime expectancy of the battery can normally be estimated based on this information if cycle count is known. However, in certain applications with very low or no cycle count, such as with an emergency lighting control device, an alternate means of testing must be employed to determine the present and predictive state of health of the battery assembly. Lithium chemistry has no memory effect, long 15+ year lifetime, and cell capacity is degraded over life primarily from discharge/charge cycle count, depth of discharge, temperature, and terminal charge voltage. Lithium precipitation and “holes” developed in the lithium layer are factors that inhibit the design capacity of the cell assembly. Regardless the reason of capacity reduction, the testing described herein can generally predict the approximate battery state of health over lifetime.

FIG. 6B shows an example battery response curve 650 in response to a discharge impulse applied to the battery, in accordance with some embodiments. The battery discharge curve 650 shows a voltage drop 652 experienced by the battery assembly 102 based on a discharge pulse associated with the one or more diagnostic load tests. After the discharge pulse, the voltage may recover, as shown in portion 654 of FIG. 6B. As an example, battery manufacturers publish battery discharge curves for different cell types, ampacity, temperature, lifetime cycle count, etc. A lifetime expectancy of the battery can normally be estimated based on this information if cycle count is known. However, in certain applications with very low or no cycle count, such as with a backup battery system (e.g., the battery assembly 102), an alternate means of testing must be employed to determine the present and predictive state of health of the battery assembly 102. Lithium chemistry has no memory effect, long 15+ year lifetime, and cell capacity may be degraded over life primarily from discharge/charge cycle count, depth of discharge, temperature, and terminal charge voltage. Lithium precipitation and “holes” developed in the lithium layer are factors that inhibit the design capacity of the cell assembly. Regardless the reason of capacity reduction, the testing described herein can generally predict the approximate battery state of health over lifetime.

FIG. 7A shows an example test curve 700 utilized for predictive maintenance, in accordance with some embodiments.

A first test method is a voltage over time test (V/T) (e.g., V/T test 701), and a second test is an impulse discharge test (e.g., Vdiff test 703). The battery will start off near a maintained (e.g., fixed) voltage, as shown by point 702. In an example, the battery assembly 102 is maintained at a fixed voltage near 14V to 14.4V. To execute these tests, the control board 110 is configured to implement the diagnostic load tests based on activation of a test switch 204. The control board 110 may cause a first load control board 120 (e.g., high current load control board) and a second load control board 130 (e.g., constant/lower current load control board) to implement one or more diagnostic load tests. For example, the first load control board 120 may be configured to implement Vdiff test 703 (e.g., high current test) and the second load control board 130 may be configured to implement V/T test 701. For example, output current of the battery system 103 may be regulated at 1 A. The activation of the constant current test drain rate (e.g., at a current value corresponding to around 1-3% of the load battery current capability in Ah) is indicated by point 704. Once the constant current test drain rate is established, a base battery drain curve is now established and will continue for several minutes. At a predetermined point 706 (e.g., at 13.8 V), an impulse test resistor (e.g., load resistor 128) is energized to perform the Vdiff test 703 on the battery assembly 102, indicated by point 708, to a high amp draw (e.g., at a current value corresponding to around 8-12% of the load battery current capability) for a few seconds. The battery voltage will droop and rebound to a distinct lower voltage, indicated by point 710. The difference in voltage between points 706 and 710 can be captured, logged, and then compared to known acceptable values for the battery assembly 102. Results may be indicated by a pass/fail score, or as an Ah capacity value. Point 714 is shown to contrast the bump test performed at the bottom of the curve with a bump test performed towards the top of the curve (e.g., at point 708). Although both points 708 and 714 are both in the exponential area of the curve, greater differential results may be obtained from a Vdiff test (e.g., Vdiff test 703) performed at the point 708 than from a Vdiff test (e.g., Vdiff test 705) performed at the point 714.

When the constant current test drain rate is established, the battery drain curve in the exponential area will continue for several minutes before leveling off. Points 706 and 712 are two pre-established voltage monitoring points and the time it takes for the battery to discharge between these two points may vary based on the state of capacity or state of health of the battery assembly 102. A healthy battery assembly 102 may take a longer period of time to discharge between points 706 and 712, as compared to a degraded battery assembly 102 that will have a shorter time period between points 706 and 712. At one or more of the points (e.g., points 702, 704, 706, 708, 710, 712, 714, other points or any combination thereof), the V/T test data (e.g., battery data) may be captured and saved. For example, one or more values associated with one or more parameters may be captured and saved at each of the one or more points. The one or more parameters may comprise one or more of a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly. The one or more values may be compared and analyzed to determine a state of health of the battery assembly 102. One or more actions may be taken based on the state of the health of the battery assembly 102. For example, the battery assembly 102, one or more battery assemblies 102, and/or one or more batteries of the battery assembly 102 may be replaced based on a state of health determination/indication below a threshold value.

In the example of FIG. 7A, the range 720 of voltage values of the battery is around 13.2V to 14.2V, which is within an exponential region of the battery discharge curve (e.g., exponential region 614, FIG. 6A). Because the full voltage of the battery is 14.4 V, and the end voltage of the battery after the tests is 13.2V if all V/T test 701, Vdiff test 703, and Vdiff test 705 are performed, or around 13.6V if only V/T test 701 and Vdiff test 703 are performed. Stated another way, the V/T and V/diff tests disclosed herein resemble comprehensive mini load tests that enable the health of the battery to be determined without significantly discharging the battery.

FIG. 7B shows an example test curve 730 that may be utilized for predictive maintenance, in accordance with some embodiments. Specifically, the example test curve 730 shows several subsequent test data sets obtained from the test battery of FIG. 7A. Note as battery ampacity lowers, the V/T and impulse discharge test results are very easy to distinguish or differentiate between the various levels at a given temperature.

FIG. 7C illustrates an example test curve 750 for a battery (or a battery string) of battery assembly 102, in accordance with some embodiments. Note that the example test curve 750 in FIG. 7C is not drawn to scale. The test curve 750 corresponds to a test sequence that includes a Vdiff test 752 followed by a V/T test 754. In accordance with some embodiments, the test sequence corresponding to test curve 750 is automatically performed by battery analysis system 100. In some embodiments, the test sequence is automatically performed at one or more predetermined time intervals (e.g., weekly, fortnightly, monthly, or quarterly).

Referring to FIG. 7C, at time t=0, the battery (or battery string) has a voltage value of V0. In some embodiments, V0 is the nominal voltage value of the battery. In some embodiments, the test sequence begins at time t=T1, when the control board 110 sends a command to charge the battery (or battery string) from voltage value V0 to voltage value V1 (e.g., via power source 101). At time T1, the battery (or battery string) achieves a voltage value of V1 and charging stops. In some instances, when charging stops (and if there is a load on the battery), the voltage of the battery (or battery string) can discharge from voltage value V1 at time T2 to voltage value V2 at time T3, as shown in FIG. 7C.

In some embodiments, at time T3, the control board 110 automatically executes Vdiff test 752 by providing a load that is around 10% (or 8-12%) of the capacity of the battery (or battery string). In some embodiments, the load is applied for a predetermined time duration, corresponding to the difference between time T4 and time T3. For example, the predetermined time duration can be a few seconds, up to 1 minute, up to 3 minutes, or up to 5 minutes. In some embodiments, the load is applied until the battery (or battery string) discharges to predetermined voltage value of V3. In the example of FIG. 7C, the battery (or battery string) attains a voltage value of V3 at time T4. The load is removed at time T4. The voltage value stabilizes at V3 between time T4 and T5, and then rebounds to voltage value V4 at time T6. In some embodiments, the control board 110 captures the voltage difference V2 (when the load is first applied) and V4 (the rebounded value), and compares it with known acceptable values for the battery assembly 102. In accordance with some embodiments, a smaller difference between V2 and V4 (i.e., a bigger rebound rebound) indicates a healthier battery whereas a larger difference between V2 and V4 (i.e., a smaller voltage rebound) indicates a more degraded battery.

With continued reference to FIG. 7C, in some embodiments, at time T6, the control board 110 sends a command to recharge the battery (or battery string) from voltage value V4. FIG. 7C shows the battery (or battery string) is recharged from voltage value V4 at time T6 to voltage value V1 at time T7. In some embodiments, the battery (or battery string) can be recharged to a different voltage value other than V1. At time T7, the battery (or battery string) attains voltage value V1 and charging is stopped. FIG. 7C shows that at time T7, the control board 110 automatically executes V/T test 754. For example, the control board 110 can send a command to load control board 130 to provide, via power resistors 136, a load that is around 1% (e.g., 1-3%) of the capacity of the battery (or battery string). The control board 110 measures the time taken for the battery (or battery string) to discharge from voltage value V1 to a predefined voltage value V5. In the example of FIG. 7C, the time taken is represented by the difference between T8 and T7, and is indicative of battery health. For example, a healthy battery can take a longer time to discharge compared to a degraded battery (i.e., the difference between T8 and T7 is larger for a healthier battery). Depending on the actual value of V1 and V5, and the capacity of the battery, the duration of V/T test 754 can take around 3-10 minutes. FIG. 7C shows that the completion of the V/T test occurs at time T8. At time T8, the control board 110 sends a command to recharge the battery (or battery string) via power source 101. The battery (or battery string) stops charging at time T9 when it reaches the nominal voltage value V0.

In accordance with some embodiments, the voltage values V0, V1, V2, V3, V4, and V5 all lie within an exponential region of the discharge curve of the battery (or battery string), such as the exponential region 614 of battery discharge curve 600 in FIG. 6A. Stated another way, Vdiff test 752 and V/T test 754 are performed at battery voltage values that are within the exponential region of the battery discharge curve, because the trends in the battery characteristics in the exponential region are indicative of the health of the battery.

FIG. 7D illustrates an example test curve 760 for a respective battery or a battery string of battery assembly 102, in accordance with some embodiments. Note that the example test curve 760 is not drawn to scale. In accordance with some embodiments, the test sequence illustrated by test curve 760 is automatically performed by battery analysis system 100 (e.g., control board 110). In some embodiments, the test sequence is automatically performed at one or more predetermined time intervals (e.g., weekly, fortnightly, monthly, or quarterly).

In the example of FIG. 7D, the voltage values ranging the lower limit V_E to the upper limit V_B all lie within the exponential region of the voltage discharge curve. The example test curve 760 shows a test sequence that includes two Vdiff tests-namely Vdiff test 762A and Vdiff test 762B—and a V/T test 764. Although the example of FIG. 7D shows a sequence where two Vdiff tests are first performed, followed by one V/T test, it will be apparent to one of ordinary skill in the art that some test sequences can include one or more V/T tests that are performed before one or more Vdiff tests, or any combination or arrangement of Vdiff and V/T tests. In some embodiments, some aspects of Vdiff test 762A and Vdiff test 762B are similar to those of Vdiff test 752 that is discussed in FIG. 7C. In some embodiments, some aspects of V/T test 764 are similar to those of V/T test 754. These similarities are not repeated for the sake of brevity.

In some embodiments, the Vdiff test 762A/762B differs from the Vdiff test 752 in that after the “high load” (e.g., corresponding to a current value of around % of the load battery current capability) is applied at voltage V_C (at time t_C for Vdiff test 762A and t_I for Vdiff test 762B), and causes the battery (or battery string) to discharge from V_C to V_E, and rebound to voltage V_D (at time t_F for Vdiff test 762A and time t_L for Vdiff test 762B), the battery (or battery string) is allowed to stabilize/equilibrate before it is recharged. the battery stabilization/equilibrating phase is shown between time t_F and time t_G for Vdiff test 762A, and between time t_L and time t_M for Vdiff test 762B. In some embodiments, during the battery stabilization/equilibrating phase, the voltage value of the battery (or battery string) may decrease from voltage value V_D to voltage value V_F, as illustrated in FIG. 7D.

The example of FIG. 7D shows that Vdiff test 762A spans a time duration indicated by the difference between time T_G and time T_C. Vdiff test 762B spans a time duration indicated by the difference between time T_M and time T_I. In some embodiments, the time it takes to complete a Vdiff test is less than one minute, less than two minutes, or less than three minutes. In accordance with some embodiments, by measuring a difference in value between V_C and V_D, the health of the battery (or battery string) can be determined. For example, as the battery starts to degrade, the amount of voltage rebound can reduce. In other words, a smaller difference in value between V_C and V_D can indicate a healthier battery, whereas a larger difference in value between V_C and V_D can indicate that the health of the battery has deteriorated.

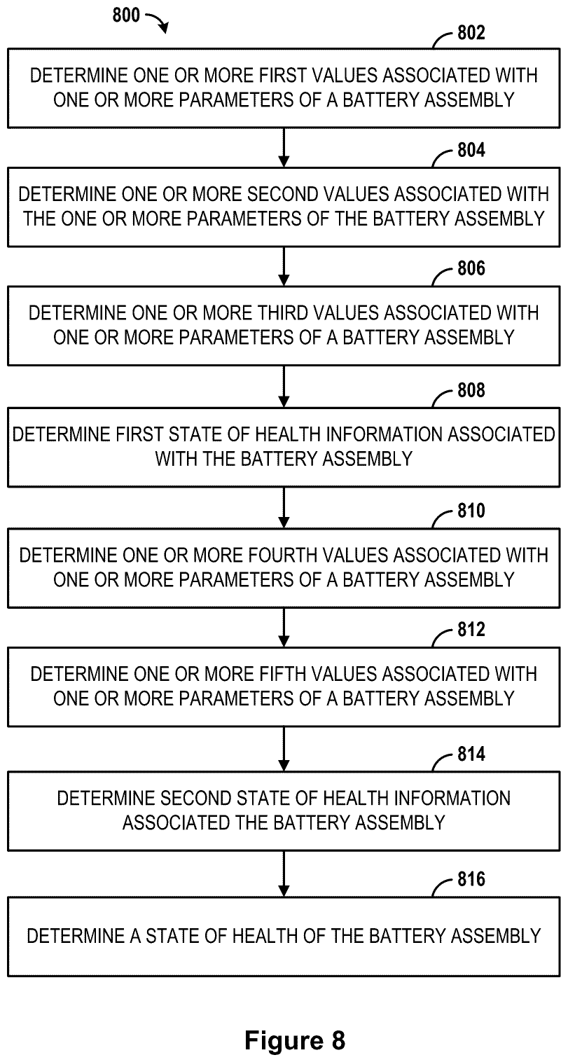

FIG. 8 shows a flowchart of an example method 800 for battery predictive analysis, in accordance with some embodiments. Method 800 may be implemented, for example, by a computing device (e.g., computer system, battery analysis system 100 that includes control board 110, current boards 120, 130, and/or 140) that includes one or more processors (e.g., processor(s) 230) and memory (e.g., memory 240). In some embodiments, the memory stores one or more programs or instructions configured for execution by the one or more processors. In some embodiments, the operations shown in FIGS. 1, 2, 3, 4, 4A, 4B, 5, 6A, 6B, and 7A to 7D correspond to instructions stored in the memory or other non-transitory computer-readable storage medium. The computer-readable storage medium may include a magnetic or optical disk storage device, solid state storage devices such as Flash memory, or other non-volatile memory device or devices. In some embodiments, the instructions stored on the computer-readable storage medium include one or more of: source code, assembly language code, object code, or other instruction format that is interpreted by one or more processors. Some operations in the method 800 may be combined with operations in the method 900, and/or the order of some operations may be changed.

At step 802, one or more first values associated with one or more parameters of a battery assembly (e.g., battery assembly 102) may be determined. For example, the one or more first values associated with the one or more parameters of the battery assembly may be determined by the computing device (e.g., battery analysis system 100, control board 110) that includes one or more processors and memory. The one or more parameters may comprise one or more of: a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly. The battery assembly may comprise at least one rechargeable battery. In an example, the one or more first values may be determined prior to a first discharge of the battery assembly. For example, the computing device may cause the battery assembly to disconnect from a power system to perform one or more diagnostic load tests of the battery assembly. In some embodiments, the one or more diagnostic load tests can include one or more Vdiff tests and/or one or more V/T tests. In an example, a relay device may be connected between the battery assembly and the power system. The relay device may be configured to open and close the connection between the battery assembly and the power system. The computing device may cause the battery assembly to disconnect from the power system based on causing the relay device to open the connection between the battery assembly and the power system.

At step 804, one or more second values associated with the one or more parameters of the battery assembly may be determined based on the first discharge of the battery assembly according to a first current. For example, the one or more second values associated with the one or more parameters of the battery assembly may be determined by the computing device (e.g., control board 110) based on the first discharge of the battery assembly according to the first current. The first discharge of the battery assembly may be caused by a first load control board (e.g., high current load control board), by executing a Vdiff test. In an example, the first discharge of the battery assembly may be caused by the first load control board via a resistor assembly (e.g., load resistor 128). In some embodiments, the resistor assembly may comprise a load resistor bank. In some embodiments, the computing device is configured to determine a resistor value to be applied (e.g., via load resistor 128) for the Vdiff test, so as to apply a load to the battery (e.g., first current) that is around 8-12% of the battery capacity. As an example, after the battery assembly disconnects from the power system, the computing device may cause the battery assembly to discharge according to the first current.

At step 806, one or more third values associated with the one or more parameters of the battery assembly may be determined based on a first recharge of the battery assembly. For example, the one or more third values associated with the one or more parameters of the battery assembly may be determined by the computing device (e.g., control board 110) based on the first recharge of the battery assembly.

At step 808, first state of health information associated with the battery assembly may be determined based on the one or more first values, the one or more second values, and the one or more third values. For example, the first state of health information associated with the battery assembly may be determined by the computing device (e.g., control board 110) based on the one or more first values, the one or more second values, and the one or more third values. For example, the first state of health information may comprise a state of health determination of the battery assembly based on implementing a high current test.

At step 810, one or more fourth values associated with the one or more parameters of the battery assembly may be determined based on a second discharge of the battery assembly according to a second current. For example, the one or more fourth values associated with the one or more parameters of the battery assembly may be determined by the computing device (e.g., control board 110) based on the second discharge of the battery assembly according to the second current. The second discharge of the battery assembly may be caused by a second load control board (e.g., constant/low current board), by executing a V/T test. In some embodiments, the computing device is configured to determine a resistor value to be applied (e.g., via the power resistors 136) for the V/T test, so as to provide a load (e.g., the current current) that is around 1-3% of the load battery current capability (e.g., in ampere hours). The first current may greater than the second current. For example, the first current may comprise 4 A to 100 A and the second current may comprise 4 A or less. In some embodiments, the

At step 812, one or more fifth values associated with the one or more parameters of the battery assembly may be determined based on a second recharge of the battery assembly. For example, the one or more fifth values associated with the one or more parameters of the battery assembly may be determined by the computing device (e.g., control board 110) based on the second recharge of the battery assembly.

At step 814, second state of health information associated with the battery assembly may be determined based on the one or more third values, the one or more fourth values, and the one or more fifth values. For example, the second state of health information associated with the battery assembly may be determined by the computing device (e.g., control board 110) based on the one or more third values, the one or more fourth values, and the one or more fifth values. For example, the second state of health information may comprise a state of health determination of the battery assembly based on implementing a constant/low current test.

At step 816, a state of health the battery assembly may be determined based on the first state of health information and the second state of health information. For example, the state of health of the battery assembly may be determined by the computing device (e.g., control board 110) based on the first state of health information and the second state of health information. In an example, one or more actions may be taken based on the state of the health of the battery assembly. For example, the battery assembly, one or more battery assemblies, and/or one or more batteries of the battery assembly may be replaced based on a state of health determination/indication below a threshold value.

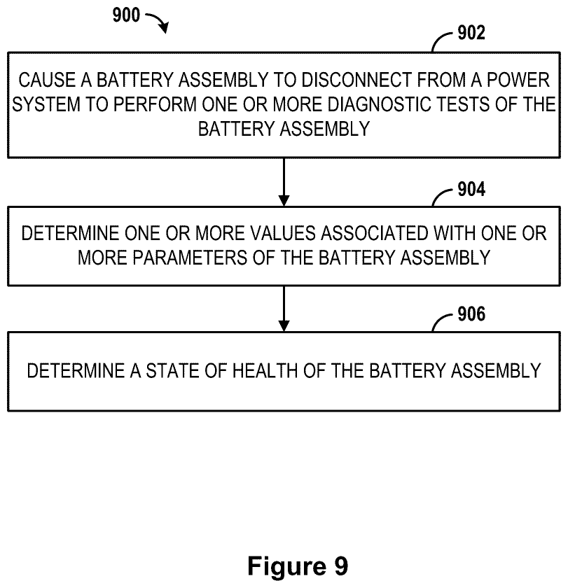

FIG. 9 shows a flowchart of an example method 900 for battery predictive analysis, in accordance with some embodiments. Method 900 may be implemented, for example, by a computing device (e.g., computer system, battery analysis system 100 that includes control board 110, current boards 120, 130, and/or 140) that includes one or more processors (e.g., processor(s) 230) and memory (e.g., memory 240). In some embodiments, the memory stores one or more programs or instructions configured for execution by the one or more processors. In some embodiments, the operations shown in FIGS. 1, 2, 3, 4, 4A, 4B, 5, 6A, 6B, and 7A to 7D correspond to instructions stored in the memory or other non-transitory computer-readable storage medium. The computer-readable storage medium may include a magnetic or optical disk storage device, solid state storage devices such as Flash memory, or other non-volatile memory device or devices. In some embodiments, the instructions stored on the computer-readable storage medium include one or more of: source code, assembly language code, object code, or other instruction format that is interpreted by one or more processors. Some operations in the method 900 may be combined with operations in the method 800, and/or the order of some operations may be changed.

At step 902, a computing device (e.g., battery analysis system 100 or control board 110) that includes one or more processors and memory may cause a battery assembly to disconnect from a power system to perform one or more diagnostic load tests of the battery assembly. The one or more diagnostic load tests may includes one or more Vdiff tests and/or one or more V/T tests. The battery assembly may comprise at least one rechargeable battery. In an example, a relay device may be connected between the battery assembly and the power system. The relay device may be configured to open and close the connection between the battery assembly and the power system. The computing device may cause the battery assembly to disconnect from the power system based on causing the relay device to open the connection between the battery assembly and the power system. After the battery assembly disconnects from the power system, the computing device may cause the battery assembly to discharge at a first time point for a first duration according to a first current (e.g., corresponding to a V/T test) and cause the battery assembly to discharge at a second time point for a second duration according to a second current (e.g., corresponding to a Vdiff test). For example, the first current comprises a load that is around 1-3% of the load battery current capability (e.g., expressed in ampere hours) and the second current comprises a load that is around 8-12% of the load battery current capability (e.g., expressed in ampere hours). The first duration may be greater than the second duration. For example, the first duration may be 3-10 minutes and the second duration is under 3 minutes. The second current may be greater than the first current. For example, the first current may comprise 4 A or less and the second current may comprise 4 A to 100 A. The discharge at the first time point may be caused by a first current board (e.g., constant/low current board) and the second discharge at the second time point may be caused by a second load control board (e.g., high current board). The discharge at the second time point may be caused by the second load control board via a resistor assembly. The resistor assembly may comprise a load resistor bank.

At step 904, one or more values associated with one or more parameters of the battery assembly may be determined at one or more time points based on the one or more diagnostic load tests of the battery assembly. For example, the one or more values associated with the one or more parameters of the battery assembly may be determined by the computing device (e.g., control board 110) at the one or more time points based on the one or more diagnostic load tests of the battery assembly. The one or more parameters may comprise one or more of a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly. The one or more time points may comprise one or more of a time point prior to the discharge of the battery assembly at the first time point, a time point after the first time point, a time point after the second time point, or a time point after the reconnection of the battery assembly to the power system.

At step 906, a state of health of the battery assembly may be determined based on the one or more values. For example, the state of health of the battery assembly may be determined by the computing device (e.g., control board 110) based on the one or more values. In an example, one or more actions may be taken based on the state of the health of the battery assembly. For example, the battery assembly, one or more battery assemblies, and/or one or more batteries of the battery assembly may be replaced based on a state of health determination/indication below a threshold value.

While the methods and systems have been described in connection with specific examples, it is not intended that the scope be limited to the particular embodiments set forth, as the embodiments herein are intended in all respects to be illustrative rather than restrictive. In some embodiments, some of the steps described in method 900 can be combined with some of the steps described in method 800.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

Some embodiments or implementations are described with respect to the following clauses:

Clause 1. An apparatus, comprising:
a battery assembly connected to a power system;
a first load control board configured to draw a first current from the battery assembly;
a second load control board configured to draw a second current from the battery assembly; and
a control board configured to:
cause a first disconnection of the battery assembly from the power system;
cause, based on sending a first command to the first load control board, the first load control board to discharge the battery assembly at a first time point based on drawing the first current from the battery assembly;
cause a first reconnection of the battery assembly to the power system to recharge the battery assembly;
cause, based on the recharge of the battery assembly, a second disconnection of the battery assembly from the power system;
cause, based on sending a second command to the second load control board, the second load control board to discharge the battery assembly at a second time point based on drawing the second current from the battery assembly; and
cause a second reconnection of the battery assembly to the power system.

Clause 2. The apparatus of Clause 1, wherein the battery assembly comprises at least one rechargeable battery.

Clause 3. The apparatus of any of Clauses 1-2, further comprising:
a relay device configured to open and close a connection between the battery assembly and the power system,
wherein the battery assembly is connected to the power system via the connection.

Clause 4. The apparatus of Clause 3, wherein the control board is configured to cause the first disconnection and the second disconnection based on causing the relay device to open the connection between the battery assembly and the power system.

Clause 5. The apparatus of any of Clauses 3-4, wherein the control board is configured to cause the first reconnection and the second reconnection based on causing the relay device to close the connection between the battery assembly and the power system.

Clause 6. The apparatus of any of Clauses 3-5, further comprising:
a resistor assembly connected between the battery assembly and the relay device,
wherein the first load control board is configured to draw the first current via the resistor assembly.

Clause 7. The apparatus of Clause 6, wherein the resistor assembly comprises a load resistor bank.

Clause 8. The apparatus of any of Clauses 1-7, wherein the first load control board comprises a load switch configured to open and close a connection between the battery assembly and the first load control board, wherein the first load control board is configured to draw the first current from the battery assembly via the connection between the battery assembly and the first load control board.

Clause 9. The apparatus of any of Clauses 1-8, wherein the first current is greater than the second current.

Clause 10. The apparatus of any of Clauses 1-9, wherein the first current comprises 4 A to 100 A.

Clause 11. The apparatus of any of Clauses 1-10, wherein the second load control board comprises a load switch configured to open and close a connection between the battery assembly and the second load control board, wherein the second load control board is configured to draw the second current from the battery assembly via the connection between the battery assembly and the second load control board.

Clause 12. The apparatus of any of Clauses 1-11, wherein the second current comprises 4 A or less.

Clause 13. The apparatus of any of Clauses 1-12, wherein the control board is configured to cause the first load control board to discharge the battery assembly for a first duration, and wherein the control board is configured to cause the second load control board to discharge the battery assembly for a second duration, wherein the second duration is greater than the first duration.

Clause 14. The apparatus of any of Clauses 1-13, further comprising:
a computing system configured to:
determine, prior to the discharge of the battery assembly at the first time point, one or more first values associated with one or more parameters of the battery assembly;
determine one or more second values associated with the one or more parameters of the battery assembly during the discharge of the battery assembly based on drawing the first current from the battery assembly;
determine one or more third values associated with the one or more parameters of the battery assembly based on the recharge of the battery assembly; and
determine, based on the one or more first values, the one or more second values, and the one or more third values, first state of health information associated with the battery assembly.

Clause 15. The apparatus of Clause 14, wherein the one or more parameters comprise one or more of: a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly.

Clause 16. The apparatus of any of Clauses 14-15, wherein the computing system is further configured to:
determine one or more fourth values associated with the one or more parameters of the battery assembly during the discharge of the battery assembly based on drawing the second current from the battery assembly;
determine one or more fifth values associated with the one or more parameters of the battery assembly based on a second recharge of the battery assembly, wherein the second recharge of the battery assembly is caused based on the second reconnection of the battery assembly to the power system; and
determine, based on the one or more third values, the one or more fourth values, and the one or more fifth values, second state of health information associated with the battery assembly.

Clause 17. The apparatus of Clause 16, wherein the computing system is further configured to:
determine, based on the first state of health information and the second state of health information, a state of health of one or more battery cells associated with the battery assembly.

Clause 18. An apparatus, comprising:
a battery assembly connected to a power system;
a first load control board configured to draw a first current from the battery assembly;
a second load control board configured to draw a second current from the battery assembly; and
a control board configured to:
cause a disconnection of the battery assembly from the power system;
cause, based on sending a first command to the first load control board, the first load control board to discharge the battery assembly at a first time point for a first duration based on drawing the first current from the battery assembly;
cause, based on sending a second command to the second load control board, the second load control board to discharge the battery assembly at a second time point for a second duration based on drawing the second current from the battery assembly; and
cause a reconnection of the battery assembly to the power system.

Clause 19. The apparatus of Clause 18, wherein the battery assembly comprises at least one rechargeable battery.

Clause 20. The apparatus of any of Clauses 18-19, further comprising:
a relay device configured to open and close a connection between the battery assembly and the power system,
wherein the battery assembly is connected to the power system via the connection.

Clause 21. The apparatus of Clause 20, wherein the control board is configured to cause the disconnection based on causing the relay device to open the connection between the battery assembly and the power system.

Clause 22. The apparatus of any of Clauses 20-21, wherein the control board is configured to cause the reconnection based on causing the relay device to close the connection between the battery assembly and the power system.

Clause 23. The apparatus of any of Clauses 20-22, further comprising:
a resistor assembly connected between the battery assembly and the relay device,
wherein the second load control board is configured to draw the second current via the resistor assembly.

Clause 24. The apparatus of Clause 23, wherein the resistor assembly comprises a load resistor bank.

Clause 25. The apparatus of any of Clauses 18-24, wherein the first load control board comprises a load switch configured to open and close a connection between the battery assembly and the first load control board, wherein the first load control board is configured to draw the first current from the battery assembly via the connection between the battery assembly and the first load control board.

Clause 26. The apparatus of any of Clauses 18-25, wherein the first current comprises 4 A or less.

Clause 27. The apparatus of any of Clauses 18-26, wherein the second load control board comprises a load switch configured to open and close a connection between the battery assembly and the second load control board, wherein the second load control board is configured to draw the second current from the battery assembly via the connection between the battery assembly and the second load control board.

Clause 28. The apparatus of any of Clauses 18-27, wherein the second current is greater than the first current.

Clause 29. The apparatus of any of Clauses 18-28, wherein the second current comprises 4 A to 100 A.

Clause 30. The apparatus of any of Clauses 18-29, wherein the first duration is greater than the second duration.

Clause 31. The apparatus of any of Clauses 18-30, further comprising:
a computing system configured to:
determine, at one or more time points, one or more values associated with one or more parameters of the battery assembly; and
determine, based on the one or more values, a state of health of the battery assembly.

Clause 32. The apparatus of Clause 31, wherein the one or more time points comprise one or more of a time point prior to the discharge of the battery assembly at the first time point, a time point after the first time point, a time point after the second time point, or a time point after the reconnection of the battery assembly to the power system.

Clause 33. The apparatus of any of Clauses 31-32, wherein the one or more parameters comprise one or more of a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly.

Clause 34. A method, comprising:
determining, by a computing device, one or more first values associated with one or more parameters of a battery assembly;
determining, based on a first discharge of the battery assembly according to a first current, one or more second values associated with the one or more parameters of the battery assembly;
determining, based on a first recharge of the battery assembly, one or more third values associated with the one or more parameters of the battery assembly;
determining, based on the one or more first values, the one or more second values, and the one or more third values, first state of health information associated with the battery assembly;
determining, based on a second discharge of the battery assembly according to a second current, one or more fourth values associated with the one or more parameters of the battery assembly;
determining, based on a second recharge of the battery assembly, one or more fifth values associated with the one or more parameters of the battery assembly;
determining, based on the one or more third values, the one or more fourth values, and the one or more fifth values, second state of health information associated with the battery assembly; and
determining, based on the first state of health information and the second state of health information, a state of health of the battery assembly.

Clause 35. The method of Clause 34, wherein the one or more parameters comprise one or more of a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly.

Clause 36. The method of any of Clauses 34-35, wherein the one or more first values are determined prior to the first discharge of the battery assembly.

Clause 37. The method of any of Clauses 34-36, wherein the battery assembly comprises at least one rechargeable battery.

Clause 38. The method of any of Clauses 34-37, wherein the first discharge of the battery assembly is caused by a first load control board and the second discharge of the battery assembly is caused by a second load control board.

Clause 39. The method of Clause 38, wherein the first discharge of the battery assembly is caused by the first load control board via a resistor assembly.

Clause 40. The method of Clause 39, wherein the resistor assembly comprises a load resistor bank.

Clause 41. The method of any of Clauses 34-40, wherein the first current is greater than the second current.

Clause 42. The method of any of Clauses 34-41, wherein the first current comprises 4 A to 100 A.

Clause 43. The method of any of Clauses 34-42, wherein the second current comprises 4 A or less.

Clause 44. A method, comprising:
causing, by a computing device, a battery assembly to disconnect from a power system to perform one or more diagnostic load tests of the battery assembly;
determining, at one or more time points, based on the one or more diagnostic load tests of the battery assembly, one or more values associated with one or more parameters of the battery assembly; and
determining, based on the one or more values, a state of health of the battery assembly.

Clause 45. The method of Clause 44, wherein the battery assembly comprises at least one rechargeable battery.

Clause 46. The method of any of Clauses 44-45, wherein the causing the battery assembly to perform the one or more diagnostic load tests of the battery assembly comprises:
causing the battery assembly to discharge at a first time point for a first duration according to a first current; and
causing the battery assembly to discharge at a second time point for a second duration according to a second current.

Clause 47. The method of Clause 46, wherein the first duration is greater than the second duration.

Clause 48. The method of any of Clauses 46-47, wherein the second current is greater than the first current.

Clause 49. The method of any of Clauses 46-48, wherein the first current comprises 4 A or less.

Clause 50. The method of any of Clauses 46-49, wherein the second current comprises 4 A to 100 A.

Clause 51. The method of any of Clauses 46-50, wherein the discharge at the first time point is caused by a first load control board and the second discharge at the second time point is caused by a second load control board.

Clause 52. The method of Clause 51, wherein the discharge at the second time point is caused by the second load control board via a resistor assembly.

Clause 53. The method of Clause 52, wherein the resistor assembly comprises a load resistor bank.

Clause 54. The method of any of Clauses 44-53, wherein the one or more time points comprise one or more of a time point prior to the discharge of the battery assembly at the first time point, a time point after the first time point, a time point after the second time point, or a time point after the reconnection of the battery assembly to the power system.

Clause 55. The method of any of Clauses 44-54, wherein the one or more parameters comprise one or more of a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly.

What is claimed is:

1. An apparatus, comprising:
a battery assembly connected to a power system;
a first load control board configured to draw a first current from the battery assembly;
a second load control board configured to draw a second current from the battery assembly; and
a control board configured to:
cause a first disconnection of the battery assembly from the power system,
cause, based on sending a first command to the first load control board, the first load control board to discharge the battery assembly at a first time point based on drawing the first current from the battery assembly,
cause a first reconnection of the battery assembly to the power system to recharge the battery assembly,
cause, based on the recharge of the battery assembly, a second disconnection of the battery assembly from the power system,
cause, based on sending a second command to the second load control board, the second load control board to discharge the battery assembly at a second time point based on drawing the second current from the battery assembly, and
cause a second reconnection of the battery assembly to the power system.

2. The apparatus of claim 1, wherein the battery assembly comprises at least one rechargeable battery.

3. The apparatus of claim 1, further comprising:
a relay device configured to open and close a connection between the battery assembly and the power system,
wherein the battery assembly is connected to the power system via the connection.

4. The apparatus of claim 3, wherein the control board is configured to cause the first disconnection and the second disconnection based on causing the relay device to open the connection between the battery assembly and the power system.

5. The apparatus of claim 3, wherein the control board is configured to cause the first reconnection and the second reconnection based on causing the relay device to close the connection between the battery assembly and the power system.

6. The apparatus of claim 3, further comprising:
a resistor assembly connected between the battery assembly and the relay device,
wherein the first load control board is configured to draw the first current via the resistor assembly.

7. The apparatus of claim 6, wherein the resistor assembly comprises a load resistor bank.

8. The apparatus of claim 1, wherein the first load control board comprises a load switch configured to open and close a connection between the battery assembly and the first load control board, wherein the first load control board is configured to draw the first current from the battery assembly via the connection between the battery assembly and the first load control board.

9. The apparatus of claim 1, wherein the first current is greater than the second current.

10. The apparatus of claim 1, wherein the first current comprises 4 A to 100 A.

11. The apparatus of claim 1, wherein the second load control board comprises a load switch configured to open and close a connection between the battery assembly and the second load control board, wherein the second load control board is configured to draw the second current from the battery assembly via the connection between the battery assembly and the second load control board.

12. The apparatus of claim 1, wherein the second current comprises 4 A or less.

13. The apparatus of claim 1, wherein the control board is configured to cause the first load control board to discharge the battery assembly for a first duration, and wherein the control board is configured to cause the second load control board to discharge the battery assembly for a second duration, wherein the second duration is greater than the first duration.

14. The apparatus of claim 1, further comprising a computing system configured to:
determine, prior to the discharge of the battery assembly at the first time point, one or more first values associated with one or more parameters of the battery assembly,
determine one or more second values associated with the one or more parameters of the battery assembly during the discharge of the battery assembly based on drawing the first current from the battery assembly,
determine one or more third values associated with the one or more parameters of the battery assembly based on the recharge of the battery assembly, and
determine, based on the one or more first values, the one or more second values, and the one or more third values, first state of health information associated with the battery assembly.

15. The apparatus of claim 14, wherein the one or more parameters comprise one or more of: a discrete cell and assembly voltage of the battery assembly, a total power available of the battery assembly, a state of charge of the battery assembly, a temperature associated with the battery assembly, an amount of power discharged by the battery assembly, or an amount of power received by the battery assembly.

16. The apparatus of claim 14, wherein the computing system is further configured to:
determine one or more fourth values associated with the one or more parameters of the battery assembly during the discharge of the battery assembly based on drawing the second current from the battery assembly,
determine one or more fifth values associated with the one or more parameters of the battery assembly based on a second recharge of the battery assembly, wherein the second recharge of the battery assembly is caused based on the second reconnection of the battery assembly to the power system, and
determine, based on the one or more third values, the one or more fourth values, and the one or more fifth values, second state of health information associated with the battery assembly.

17. The apparatus of claim 16, wherein the computing system is further configured to: determine, based on the first state of health information and the second state of health information, a state of health of one or more battery cells associated with the battery assembly.
